(19) United States
(12) Patent Application Publication
(10) Pub. No.: US 2025/0301758 A1
(43) Pub. Date: Sep. 25, 2025

(54) SEMICONDUCTOR DEVICE AND SEMICONDUCTOR MEMORY DEVICE

(71) Applicant: Kioxia Corporation, Tokyo (JP)

(72) Inventors: Akinori KAMIYAMA, Yokkaichi Mie (JP); Shosuke FUJII, Kuwana Mie (JP); Keiji IKEDA, Kawasaki Kanagawa (JP); Akira TORIUMI, Yokohama Kanagawa (JP); Kenichi HAGA, Yokkaichi Mie (JP); Satoshi HASEGAWA, Inabe Mie (JP); Takamasa HAMAI, Yokkaichi Mie (JP)

(21) Appl. No.: 19/064,572

(22) Filed: Feb. 26, 2025

(30) Foreign Application Priority Data
Mar. 19, 2024 (JP) 2024-044156

(51) Int. Cl. H10D 64/68; H10B 12/00

(52) U.S. Cl. CPC H10D 64/691; H10B 12/02; H10B 12/33

(57) ABSTRACT

A semiconductor device includes: a substrate extending in a first direction; a gate electrode extending along the first direction above the substrate; an oxide semiconductor that extends in a second direction intersecting the first direction above the substrate and penetrates the gate electrode; a first electrode electrically connected to one end of the oxide semiconductor; a second electrode electrically connected to the other end of the oxide semiconductor; and a first insulating film made of a first insulating material. The first insulating film includes: a first film portion that covers an upper surface of the gate electrode, a second film portion that covers a lower surface of the gate electrode, and a third film portion that extends in the second direction between the gate electrode and the oxide semiconductor.

### CROSS-REFERENCE TO RELATED APPLICATION(S)

This application is based upon and claims the benefit of priority from Japanese Patent Application No. 2024-044156, filed Mar. 19, 2024, the entire contents of which are incorporated herein by reference.

### FIELD

Embodiments described herein relate generally to a semiconductor device and a semiconductor memory device.

### BACKGROUND

Among semiconductor elements, there are those in which a metal oxide including indium and tin is used for an electrode.

### BRIEF DESCRIPTION OF THE DRAWINGS

FIG. 1 is a circuit drawing illustrating a circuit configuration of a memory cell array according to a first embodiment.

FIG. 2 is a sectional schematic view illustrating a structure of a semiconductor memory device according to the first embodiment, and is a sectional view parallel to a ZX plane.

FIG. 3 is a sectional schematic view illustrating a structure of a semiconductor device according to the first embodiment, and is a sectional view parallel to the ZX plane.

FIG. 4 is a sectional schematic view illustrating a structure of the semiconductor device according to the first embodiment, and is a sectional view parallel to a YZ plane.

FIG. 5 is a sectional view along a section line V-V shown in FIGS. 3 and 4.

FIG. 6 is a sectional schematic view illustrating a structure in a vicinity of a word line contact in the semiconductor device according to the first embodiment, and is a sectional view parallel to the YZ plane.

FIG. 7 is a sectional view parallel to the ZX plane showing a process of manufacturing the semiconductor device of the first embodiment.

FIG. 8 is a sectional view parallel to the YZ plane showing a process of manufacturing the semiconductor device of the first embodiment.

FIG. 9 is a sectional view parallel to the ZX plane showing a process of manufacturing the semiconductor device of the first embodiment.

FIG. 10 is a sectional view parallel to the YZ plane showing a process of manufacturing the semiconductor device of the first embodiment.

FIG. 11 is a sectional view along a section line XI-XI shown in FIGS. 9 and 10.

FIG. 12 is a sectional view parallel to the YZ plane showing a manufacturing process in a vicinity of a word line contact in the semiconductor device of the first embodiment.

FIG. 13 is a sectional view parallel to the YZ plane showing a manufacturing process in a vicinity of a word line contact in the semiconductor device of the first embodiment.

FIG. 14 is a sectional view parallel to the ZX plane showing a process of manufacturing the semiconductor device of the first embodiment.

FIG. 15 is a sectional view parallel to the YZ plane showing a process of manufacturing the semiconductor device of the first embodiment.

FIG. 16 is a sectional view parallel to the YZ plane showing a manufacturing process in a vicinity of a word line contact in the semiconductor device of the first embodiment.

FIG. 17 is a sectional view parallel to the ZX plane showing a process of manufacturing the semiconductor device of the first embodiment.

FIG. 18 is a sectional view parallel to the YZ plane showing a process of manufacturing the semiconductor device of the first embodiment.

FIG. 19 is a sectional view parallel to the YZ plane showing a manufacturing process in a vicinity of a word line contact in the semiconductor device of the first embodiment.

FIG. 20 is a sectional view parallel to the YZ plane showing a manufacturing process in a vicinity of a word line contact in the semiconductor device of the first embodiment.

FIG. 21 is a sectional view parallel to the ZX plane showing a process of manufacturing the semiconductor device of the first embodiment.

FIG. 22 is a sectional view parallel to the YZ plane showing a process of manufacturing the semiconductor device of the first embodiment.

FIG. 23 is a sectional view along a section line XXIII-XXIII shown in FIGS. 21 and 22.

FIG. 24 is a sectional view parallel to the YZ plane showing a manufacturing process in a vicinity of a word line contact in the semiconductor device of the first embodiment.

FIG. 25 is a sectional view parallel to the ZX plane showing a process of manufacturing the semiconductor device of the first embodiment.

FIG. 26 is a sectional view parallel to the YZ plane showing a process of manufacturing the semiconductor device of the first embodiment.

FIG. 27 is a sectional view parallel to the ZX plane showing a process of manufacturing the semiconductor device of the first embodiment.

FIG. 28 is a sectional view parallel to the YZ plane showing a process of manufacturing the semiconductor device of the first embodiment.

FIG. 29 is a sectional view parallel to the ZX plane showing a process of manufacturing the semiconductor device of the first embodiment.

FIG. 30 is a sectional view parallel to the YZ plane showing a process of manufacturing the semiconductor device of the first embodiment.

FIG. 31 is a sectional view parallel to the ZX plane showing a process of manufacturing the semiconductor device of the first embodiment.

FIG. 32 is a sectional view parallel to the YZ plane showing a process of manufacturing the semiconductor device of the first embodiment.

FIG. 33 is a sectional view parallel to the ZX plane showing a process of manufacturing the semiconductor device of the first embodiment.

FIG. 34 is a sectional view parallel to the YZ plane showing a process of manufacturing the semiconductor device of the first embodiment.

FIG. 35 is a sectional view along a section line XXXV-XXXV shown in FIGS. 33 and 34.

FIG. 36 is a sectional view parallel to the ZX plane showing a process of manufacturing the semiconductor device of the first embodiment.

FIG. 37 is a sectional view parallel to the YZ plane showing a process of manufacturing the semiconductor device of the first embodiment.

FIG. 38 is a sectional view parallel to the ZX plane showing a process of manufacturing the semiconductor device of the first embodiment.

FIG. 39 is a sectional view parallel to the YZ plane showing a process of manufacturing the semiconductor device of the first embodiment.

FIG. 40 is a sectional view parallel to the ZX plane showing a process of manufacturing the semiconductor device of the first embodiment.

FIG. 41 is a sectional view parallel to the YZ plane showing a process of manufacturing the semiconductor device of the first embodiment.

FIG. 42 is a sectional view parallel to the ZX plane showing a process of manufacturing the semiconductor device of the first embodiment.

FIG. 43 is a sectional view parallel to the YZ plane showing a process of manufacturing the semiconductor device of the first embodiment.

FIG. 44 is a sectional view parallel to the ZX plane showing a process of manufacturing the semiconductor device of the first embodiment.

FIG. 45 is a sectional view parallel to the YZ plane showing a process of manufacturing the semiconductor device of the first embodiment.

FIG. 46 is a sectional view parallel to the ZX plane showing a process of manufacturing the semiconductor device of the first embodiment.

FIG. 47 is a sectional view parallel to the YZ plane showing a process of manufacturing the semiconductor device of the first embodiment.

FIG. 48 is a sectional view parallel to the ZX plane showing a process of manufacturing the semiconductor device of the first embodiment.

FIG. 49 is a sectional view parallel to the YZ plane showing a process of manufacturing the semiconductor device of the first embodiment.

FIG. 50 is a sectional view parallel to the ZX plane showing a process of manufacturing the semiconductor device of the first embodiment.

FIG. 51 is a sectional view parallel to the YZ plane showing a process of manufacturing the semiconductor device of the first embodiment.

FIG. 52 is a sectional view parallel to the ZX plane showing a process of manufacturing a semiconductor device of a comparative example.

FIG. 53 is a sectional schematic view illustrating a structure of a semiconductor device according to a second embodiment, and is a sectional view parallel to a YZ plane.

FIG. 54 is a sectional view parallel to the YZ plane showing a process of manufacturing the semiconductor device of the second embodiment.

FIG. 55 is a sectional view parallel to the YZ plane showing a process of manufacturing the semiconductor device of the second embodiment.

FIG. 56 is a sectional view parallel to the YZ plane showing a process of manufacturing the semiconductor device of the second embodiment.

FIG. 57 is a sectional view parallel to the YZ plane showing a process of manufacturing the semiconductor device of the second embodiment.

FIG. 58 is a sectional view parallel to the YZ plane showing a process of manufacturing the semiconductor device of the second embodiment.

FIG. 59 is a sectional view parallel to the YZ plane showing a process of manufacturing the semiconductor device of the second embodiment.

FIG. 60 is a sectional view parallel to the YZ plane showing a process of manufacturing the semiconductor device of the second embodiment.

FIG. 61 is a sectional view parallel to the YZ plane showing a process of manufacturing the semiconductor device of the second embodiment.

FIG. 62 is a sectional view parallel to the YZ plane showing a process of manufacturing the semiconductor device of the second embodiment.

FIG. 63 is a sectional view parallel to the YZ plane showing a process of manufacturing the semiconductor device of the second embodiment.

FIG. 64 is a sectional view parallel to the YZ plane showing a process of manufacturing the semiconductor device of the second embodiment.

### DETAILED DESCRIPTION

A process of manufacturing a semiconductor element in which a metal oxide is used for an electrode requires technology such that a semiconductor device of good quality is manufactured.

Embodiments provide a semiconductor device and a semiconductor memory device such that a semiconductor device of good quality can be manufactured.

In general, according to one embodiment, a semiconductor device comprises a substrate extending in a first direction; a gate electrode extending along the first direction above the substrate; an oxide semiconductor that extends in a second direction intersecting the first direction above the substrate and penetrates the gate electrode; a first electrode electrically connected to one end of the oxide semiconductor; a second electrode electrically connected to the other end of the oxide semiconductor; and a first insulating film made of a first insulating material. The first insulating film includes: a first film portion that covers an upper surface of the gate electrode, a second film portion that covers a lower surface of the gate electrode, and a third film portion that extends in the second direction between the gate electrode and the oxide semiconductor.

Hereafter, embodiments will be described while referring to the attached drawings. In order to facilitate understanding of the description, identical reference signs will be allotted to identical components in the drawings as far as possible, and redundant descriptions will be omitted.

### First Embodiment

A configuration of a semiconductor memory device 101 according to a first embodiment will be described. X, Y, and Z axes are shown in one or more of the drawings. The X axis, the Y axis, and the Z axis form right-handed three-dimensional Cartesian coordinates. Hereafter, an X axis arrow direction may be called “an X axis + direction”, and a direction opposite to that of the arrow “an X axis − direction”, with the same applying to the other axes. The “Z axis + direction” and the “Z axis − direction” may be called “upward” and “downward” respectively. Also, planes perpendicular to the X axis, the Y axis, and the Z axis may be called a YZ plane, a ZX plane, and an XY plane respectively. Also, the Z axis direction may be called an “up-down direction”. “Upward”, “downward”, and “up-down direction” are merely terms indicating a relative positional relationship in the drawings, and are not terms that specify an orientation having a vertical direction as a reference.

In the present specification, “connection” includes not only a physical connection but also an electrical connection, and unless specifically stated otherwise, includes not only a direct connection but also an indirect connection.

In the present specification, unless specifically stated otherwise, “formed upward” includes not only a case of being formed in contact upward, but also a case of being formed upward across another object. The same applies to a case of being “formed downward”, or the like.

The semiconductor memory device 101 according to the first embodiment is an oxide semiconductor random access memory (OS-RAM), and includes a memory cell array.

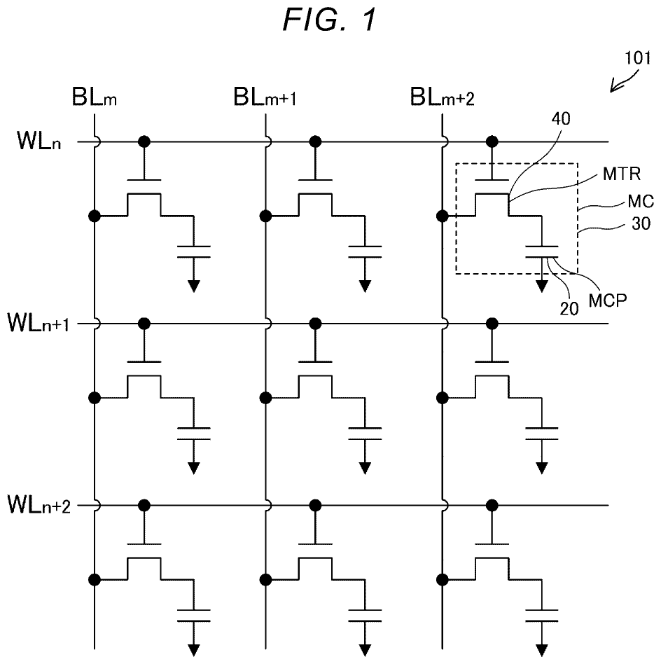

As shown in FIG. 1, a memory cell array includes a plurality of memory cells MC, a plurality of word lines WL, and a plurality of bit lines BL.

In FIG. 1, a word line WLn, a word line WLn+1, and a word line WLn+2 are shown as one example of the plurality of word lines WL (herein, n is a positive integer). Also, in FIG. 1, a bit line BLm, a bit line BLm+1, and a bit line BLm+2 are shown as one example of the plurality of bit lines BL (herein, m is a positive integer). The quantity of the memory cells MC is not limited to the quantity shown in FIG. 1.

The plurality of memory cells MC form a memory cell array by being arrayed in, for example, a matrix form. The memory cell MC includes a memory transistor MTR, which is a field-effect transistor (FET), and a memory capacitor MCP.

One series of memory cells MC provided in a row direction is connected to the word line WL (for example, the word line WLn) corresponding to the row to which the series of memory cells MC belongs (for example, the nth row). One series of memory cells MC provided in a column direction is connected to the bit line BL (for example, the bit line BLm+2) corresponding to the column to which the series of memory cells MC belongs (for example, the m+2th column).

Specifically, a gate of the memory transistor MTR in the memory cell MC is connected to the word line WL corresponding to the row to which the memory cell MC belongs. Either a source or a drain of the memory transistor MTR is connected to the bit line BL corresponding to the column to which the memory cell MC belongs.

One electrode of the memory capacitor MCP in the memory cell MC is connected to the other of the source or the drain of the memory transistor MTR in the memory cell MC. The other electrode of the memory cell MC is connected to a power supply line (not shown) that applies a specific voltage.

Using a switching of the memory transistor MTR based on a voltage of the corresponding word line WL, the memory cell MC is able to hold data owing to an accumulation of an electric charge in the memory capacitor MCP caused by a current flowing through the corresponding bit line BL.

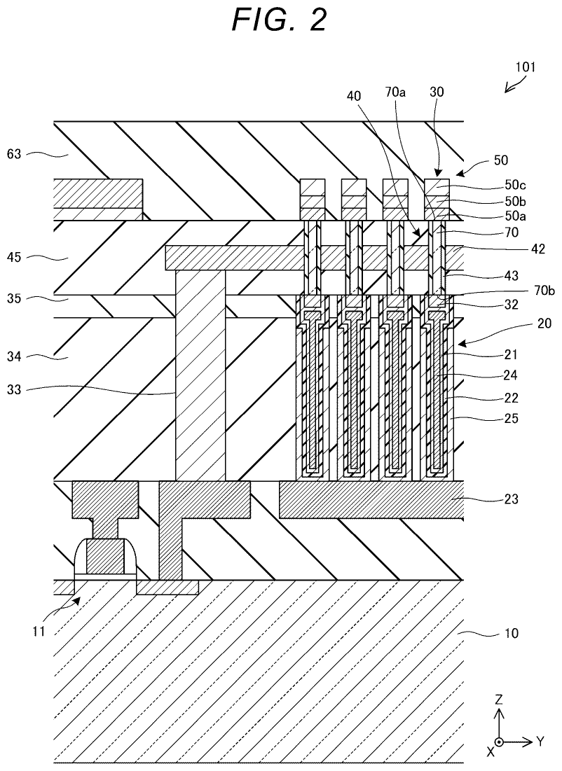

As shown in FIG. 2, the semiconductor memory device 101 includes a semiconductor substrate 10, a semiconductor circuit 11, a capacitor 20, a semiconductor device 30, a conductor 33, and insulating layers 34, 35, and 36.

The capacitor 20 includes a conductor 21, an insulating film 22 (e.g., a dielectric film), a conductor 23, a capacitor electrode 24, and a capacitor electrode 25.

The semiconductor device 30 includes a field-effect transistor 40 as a semiconductor element, an upper electrode 50 provided above the field-effect transistor 40, and a lower electrode 32 provided below the field-effect transistor 40.

The field-effect transistor 40 includes an oxide semiconductor layer 70, a gate insulating film 43, a conductive layer 42, and an insulating layer 45.

The oxide semiconductor layer 70 is formed in the insulating layer 45, and has an upper end 70a and a lower end 70b. The oxide semiconductor layer 70 has a columnar body that extends in the Z axis + direction from the lower end 70b toward the upper end 70a. The oxide semiconductor layer 70 forms a channel of the field effect transistor 40, and the oxide semiconductor layer 70 has an amorphous structure.

The conductive layer 42 opposes the oxide semiconductor layer 70 across the gate insulating film 43. Specifically, the conductive layer 42 functions as a gate electrode of the field effect transistor 40, and encloses the oxide semiconductor layer 70 across the gate insulating film 43 between the upper end 70a and the lower end 70b of the oxide semiconductor layer 70. The conductive layer 42 includes, for example, tungsten (W).

The gate insulating film 43 includes a silicon nitride film (Si3N4) containing, for example, silicon and nitrogen.

The upper electrode 50 is formed in the Z axis + direction with respect to the oxide semiconductor layer 70, and is connected to the upper end 70a of the oxide semiconductor layer 70. The upper electrode 50 includes a metal oxide layer 50a, a barrier metal layer 50b, and a metal film 50c.

The metal film 50c includes tungsten. The metal oxide layer 50a is formed between the metal film 50c and the upper end 70a of the oxide semiconductor layer 70, and includes a metal oxide. The metal oxide includes, for example, indium and tin as metallic elements. For example, the metal oxide layer 50a is formed of indium-tin-oxide (ITO).

The barrier metal layer 50b includes titanium and nitrogen, and is formed between the metal oxide layer 50a and the metal film 50c. For example, the barrier metal layer 50b is formed of titanium nitride (TiN).

The lower electrode 32 is connected to the lower end 70b of the oxide semiconductor layer 70. The lower electrode 32 includes a metal oxide. Specifically, the lower electrode 32 includes, for example, indium and tin as metallic elements. For example, the lower electrode 32 is formed of indium-tin-oxide (ITO).

The lower electrode 32, not being limited to ITO, may be of a configuration including at least any one element among indium, tin, zinc, cadmium, gold, silver, platinum, lead, copper, nickel, tungsten, and iron.

The circuit 11 is a peripheral circuit of a decoder for selecting a predetermined memory cell MC among the plurality of memory cells MC, that is, the capacitors 20 and the field-effect transistors 40, of the semiconductor memory device 101, a sense amplifier connected to the bit line BL, a register configured with an SRAM, and the like. The circuit 11 may include a CMOS circuit having field-effect transistors, which are a p-channel field-effect transistor (Pch-FET) and an n-channel field-effect transistor (Nch-FET), formed using a CMOS process.

A field-effect transistor of the circuit 11 can be formed using the semiconductor substrate 10, which is a single crystal silicon substrate or the like. The Pch-FET and the Nch-FET are so-called lateral field-effect transistors that have a channel region, a source region, and a drain region in the semiconductor substrate 10, and have a channel for causing a carrier to flow in the X axis direction and the Y axis direction, which are approximately parallel to a surface of the semiconductor substrate 10, in a region near the surface of the semiconductor substrate 10. The semiconductor substrate 10 may have p-type or n-type conductivity. For the sake of convenience, FIG. 2 shows one example of a field-effect transistor of the circuit 11.

The capacitor 20 is the memory capacitor MCP in the memory cell MC (refer to FIG. 1). Although four capacitors 20 are shown in FIG. 2, the quantity of capacitors 20 is not limited to four.

Here, the capacitor 20 is provided above the semiconductor substrate 10. The capacitor electrode 24 of the capacitor 20 is connected to the conductor 21 and the lower electrode 32. The capacitor electrode 25 opposes the capacitor electrode 24. The insulating film 22 is provided between the capacitor electrode 24 and the capacitor electrode 25.

The capacitor 20 is a three-dimensional capacitor, such as a pillar-type capacitor. Another capacitor that includes a configuration such that a charge can be accumulated may be employed as a capacitor of the present embodiment.

The capacitor electrode 24 is positioned below the lower electrode 32. The capacitor electrode 24 has an upper end that opposes a lower end face of the lower electrode 32 across the conductor 21, and has a columnar form that extends downward from the upper end. The conductor 21 covers the lower electrode 32 and the capacitor electrode 24. The insulating film 22 covers the conductor 21. The capacitor electrode 25 has a lower end that encloses a lower portion of the insulating film 22 and is in contact with an upper end face of the conductor 23.

The capacitor electrode 24 may include a material, such as SiGe, containing silicon and germanium. The insulating film 22 may include a material, such as ZrAlO, containing zirconium, aluminum, and oxygen. The conductor 21 may include a material, such as titanium nitride, containing nitrogen and titanium. The conductor 23 and the capacitor electrode 25 may include materials such as tungsten and titanium nitride.

The conductor 33 includes wiring that electrically connects the circuit 11 and the semiconductor device 30. The conductor 33 may include via wiring, extends in the Z axis direction as shown in, for example, FIG. 2, and has via wiring that connects the word line WL and the circuit 11 provided on the semiconductor substrate 10. The conductor 33 includes, for example, copper.

The insulating layer 34 is provided among the plurality of capacitors 20. The insulating layer 34 is a silicon oxide film containing, for example, silicon and oxygen.

The insulating layer 35 is provided above the insulating layer 34. The insulating layer 35 is a silicon nitride film containing, for example, silicon and nitrogen.

The semiconductor device 30 is provided above the capacitor 20. The field-effect transistor 40 in the semiconductor device 30 corresponds to the memory transistor MTR of the memory cell MC (refer to FIG. 1).

In the semiconductor device 30, the field-effect transistor 40 is provided above the lower electrode 32. Specifically, the oxide semiconductor layer 70 of the field-effect transistor 40 is positioned in a direction away from the semiconductor substrate 10, that is, upward, with respect to the lower electrode 32.

The upper electrode 50 is positioned in a direction away from the semiconductor substrate 10, that is, upward, with respect to the oxide semiconductor layer 70. By including this kind of configuration, the field-effect transistor 40 is a so-called vertical transistor having a channel that extends in the Z axis direction (i.e., the up-down direction), which is approximately vertical to the surface of the semiconductor substrate 10.

Also, the oxide semiconductor layer 70 is a semiconductor such that an oxygen vacancy is a donor, and includes indium (In), zinc (Zn), and gallium (Ga) as metallic elements. Specifically, the oxide semiconductor layer 70 is an oxide of indium, gallium, and zinc, that is, an IGZO (InGaZnO). The oxide semiconductor layer 70 may also be another kind of oxide semiconductor.

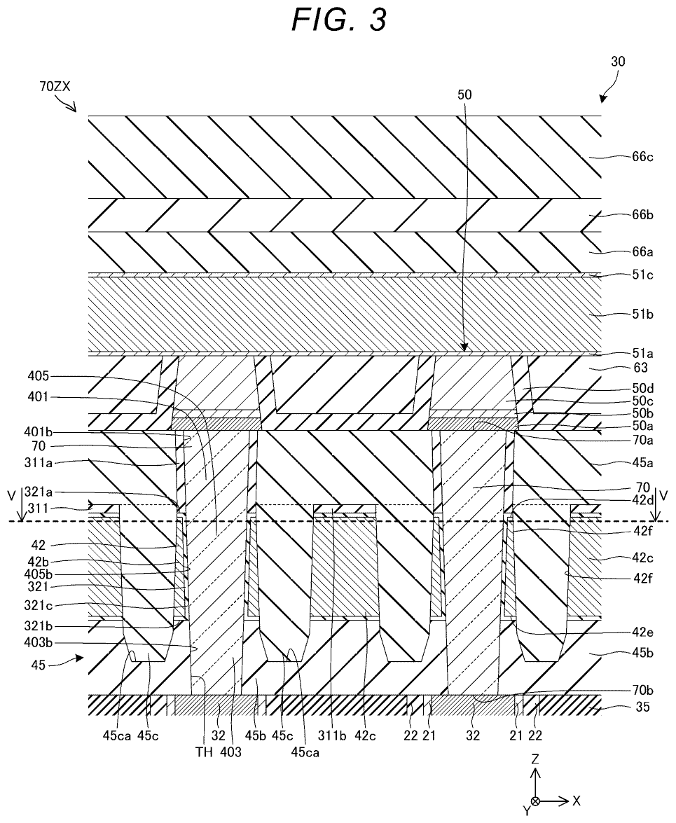

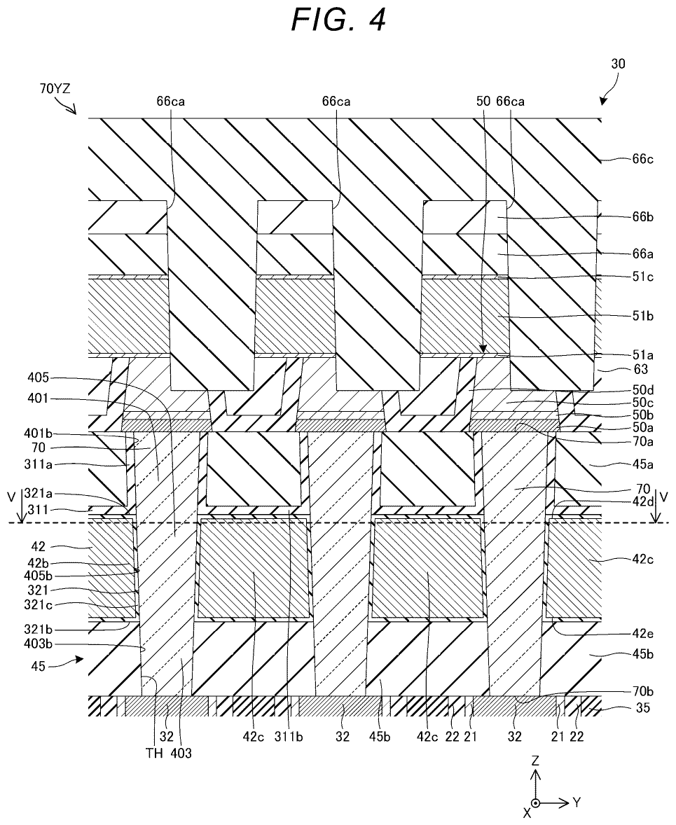

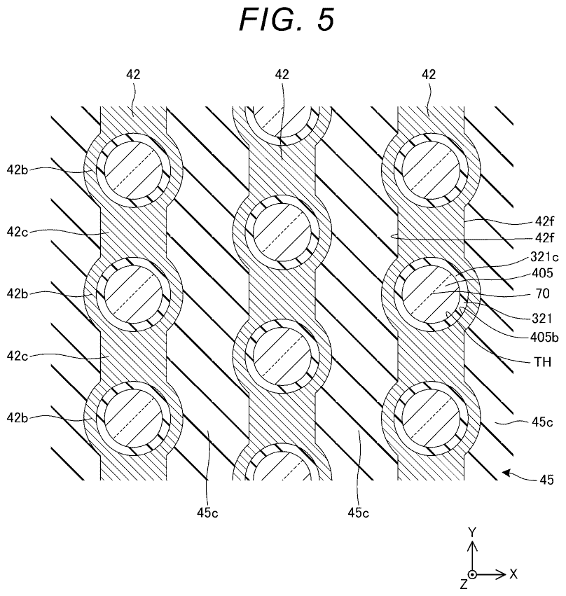

FIG. 3 is a cross-section 70ZX that is parallel to the ZX plane, and is a sectional view of the semiconductor device 30 when seen in the cross-section 70ZX in the oxide semiconductor layer 70. FIG. 4 is a cross-section 70YZ that is parallel to the YZ plane, and is a sectional view of the semiconductor device 30 when seen in the cross-section 70YZ in the oxide semiconductor layer 70. FIG. 5 is a sectional view along a section line V-V shown in FIGS. 3 and 4.

As shown in FIGS. 3 to 5, the semiconductor device 30 differs from the semiconductor device 30 shown in FIG. 2 in including an insulating film 321 instead of the gate insulating film 43, and further including a spacer film 311. The insulating layer 45 includes insulating films 45a, 45b, and 45c.

The plurality of conductive layers 42 are provided repeatedly in the X axis direction. The plurality of oxide semiconductor layers 70 are arrayed two-dimensionally. That is, one portion of the plurality of oxide semiconductor layers 70 are provided repeatedly in the Y axis direction. Also, the other portion of the plurality of oxide semiconductor layers 70 are provided repeatedly in the X axis + direction.

The conductive layer 42 is formed of a first conductive material. For example, the conductive layer 42 includes tungsten. The conductive layer 42 may include another element.

The conductive layer 42 extends in the Y axis direction. Specifically, the conductive layer 42 includes an enclosing portion 42b, which encloses the oxide semiconductor layer 70, and a linking portion 42c that links two enclosing portions 42b.

A hole portion 405 extending in the up-down direction is formed in the enclosing portion 42b of the conductive layer 42. The oxide semiconductor layer 70 penetrates the hole portion 405.

When the conductive layer 42 is seen from above, a width in the X axis direction of the linking portion 42c is smaller than a width in the X axis direction of the enclosing portion 42b.

The insulating film 321 is formed of a first insulating material. The first insulating material contains silicon and nitrogen. For example, the insulating film 321 is a nitride of silicon. The insulating film 321 may also be an oxide of silicon, an oxide of hafnium, an oxide of aluminum, or the like.

The insulating film 321 includes a gate upper film portion 321a, a gate lower film portion 321b, and a gate insulating film portion 321c.

The gate upper film portion 321a covers an upper face 42d of the conductive layer 42. The gate lower film portion 321b covers a lower face 42e of the conductive layer 42.

The gate insulating film portion 321c covers a first face of the conductive layer 42 opposing the oxide semiconductor layer 70. Here, the gate insulating film portion 321c covers an inner wall face 405b of the hole portion 405. The gate insulating film portion 321c is in contact with the oxide semiconductor layer 70, and encloses a whole periphery of a central portion separated from the upper end 70a and the lower end 70b of the oxide semiconductor layer 70.

The gate upper film portion 321a, the gate lower film portion 321b, and the gate insulating film portion 321c are integrally formed. That is, a composition of each element in the gate upper film portion 321a, the gate lower film portion 321b, and the gate insulating film portion 321c is approximately the same.

The conductive layer 42 has a side face 42f having the X axis direction as a normal direction. The side face 42f is not covered by the insulating film 321, and is in contact with the insulating film 45c.

The insulating film 45c is formed of, for example, a second insulating material differing from the first insulating material. For example, the insulating film 45c is an oxide of silicon.

The spacer film 311 is formed of a third insulating material differing from the first insulating material. Oxygen permeability of the first insulating material is less than oxygen permeability of the third insulating material. For example, the spacer film 311 is an oxide of silicon.

A hole portion 401, which is the hole portion 401 extending in the up-down direction and which the oxide semiconductor layer 70 penetrates and is in contact with, is formed in the spacer film 311, and the spacer film 311 is provided above the gate upper film portion 321a.

Specifically, the spacer film 311 includes a cylindrical portion 311a and a plate-form portion 311b. The cylindrical portion 311a is provided above the enclosing portion 42b of the conductive layer 42 across the gate upper film portion 321a, and extends approximately parallel to the Z axis.

The cylindrical portion 311a has the hole portion 401. A lower end portion of the cylindrical portion 311a is an annular face that is in contact with the gate upper film portion 321a. An inner wall face 401b of the hole portion 401 is in contact with the oxide semiconductor layer 70, and encloses a whole periphery of one upper portion of the oxide semiconductor layer 70. The plate-form portion 311b is provided above the linking portion 42c of the conductive layer 42 across the gate upper film portion 321a, and extends in a plane approximately parallel to the XY plane.

The insulating film 45a is provided above the plate-form portion 311b. The insulating film 45a is, for example, an oxide of silicon.

The insulating film 45b is formed of a fourth insulating material differing from the first insulating material. The oxygen permeability of the first insulating material is less than oxygen permeability of the fourth insulating film. For example, the insulating film 45b is an oxide of silicon.

A hole portion 403, which is the hole portion 403 extending in the up-down direction and which the oxide semiconductor layer 70 penetrates and is in contact with, is formed in the insulating film 45b, and the insulating film 45b is provided below the gate lower film portion 321b. An inner wall face 403b of the hole portion 403 is in contact with the oxide semiconductor layer 70, and encloses a whole periphery of one lower portion of the oxide semiconductor layer 70.

The insulating film 45c separates two conductive layers 42 neighboring in the X axis direction. Specifically, the insulating film 45c is positioned between two conductive layers 42 neighboring in the X axis direction, and extends approximately parallel to the Y axis.

An upper end portion of the insulating film 45c is connected to a lower face of the insulating film 45a. A lower portion of the insulating film 45c is embedded in the insulating film 45b. Here, the insulating films 45a and 45c are integrally formed.

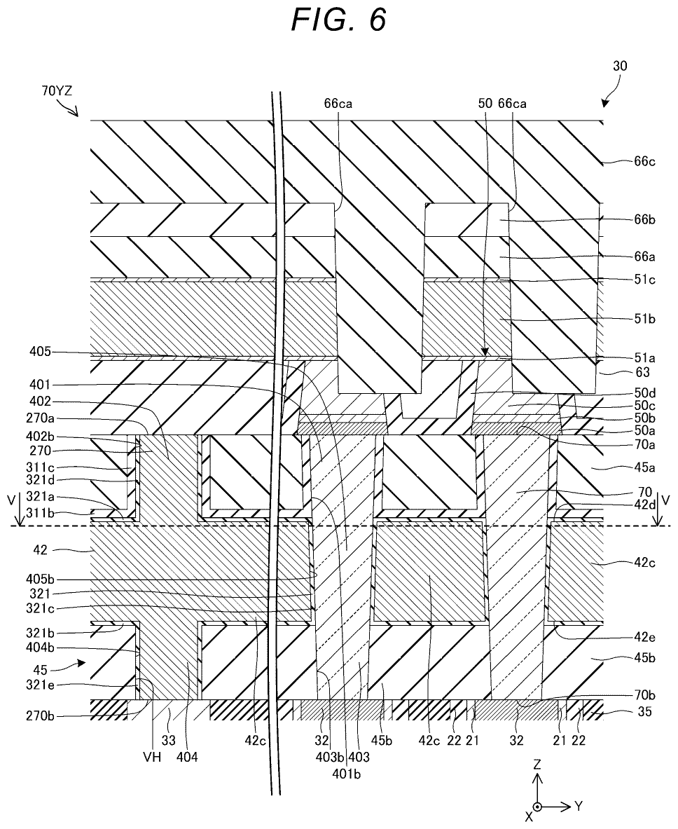

FIG. 6 is the cross-section 70YZ parallel to the YZ plane, and is a sectional view of a vicinity of a word line contact in the semiconductor device 30 when seen in the cross-section 70YZ in the oxide semiconductor layer 70.

As shown in FIG. 6, the semiconductor device 30 further includes a via electrode 270. The via electrode 270 is formed of the first conductive material. That is, the via electrode 270 includes tungsten.

The via electrode 270 is formed in the insulating layer 45, and has an upper end 270a and a lower end 270b. The via electrode 270 is a columnar body extending in the Z axis +direction from the lower end 270b toward the upper end 270a.

The via electrode 270 is electrically connected to the conductive layer 42. Here, the via electrode 270 penetrates the conductive layer 42. However, in another embodiment, the via electrode 270 may not penetrate the conductive layer 42.

A hole portion 402, which is the hole portion 402 extending in the up-down direction and which an upper portion of the via electrode 270 penetrates, is further formed in the spacer film 311.

Specifically, the spacer film 311 further includes a cylindrical portion 311c. The cylindrical portion 311c is provided above the conductive layer 42 across the gate upper film portion 321a, and extends approximately parallel to the Z axis.

The cylindrical portion 311c has the hole portion 402. A lower end portion of the cylindrical portion 311c has an annular face that is in contact with the gate upper film portion 321a of the insulating film 321.

A hole portion 404, which is the hole portion 404 extending in the up-down direction and which the via electrode 270 penetrates, is further formed in the insulating film 45b.

The insulating film 321 further includes a via upper film portion 321d and a via lower film portion 321e. The via upper film portion 321d and the via lower film portion 321e cover an inner wall face 402b of the hole portion 402 and an inner wall face 404b of the hole portion 404 respectively.

Specifically, the via upper film portion 321d has an approximately cylindrical form. An outer peripheral face of the via upper film portion 321d is in contact with a whole periphery of the inner wall face 402b of the hole portion 402. In other words, the inner wall face 402b encloses a whole periphery of the via upper film portion 321d.

An inner peripheral face of the via upper film portion 321d is in contact with a whole periphery of an upper portion of the via electrode 270. That is, the via upper film portion 321d encloses the whole periphery of the upper portion of the via electrode 270. In other words, the via upper film portion 321d covers the upper portion of the via electrode 270 between the cylindrical portion 311c and the upper portion of the via electrode 270.

The via lower film portion 321e has an approximately cylindrical form. An outer peripheral face of the via lower film portion 321e is in contact with a whole periphery of the inner wall face 404b of the hole portion 404. In other words, the inner wall face 404b encloses a whole periphery of the via lower film portion 321e.

An inner peripheral face of the via lower film portion 321e is in contact with a whole periphery of a lower portion of the via electrode 270. That is, the via lower film portion 321e encloses the whole periphery of the lower portion of the via electrode 270. In other words, the via lower film portion 321e covers the lower portion of the via electrode 270 between the insulating film 45b and the lower portion of the via electrode 270.

### Semiconductor Device Manufacturing Method

Hereafter, a method of manufacturing the semiconductor device 30 will be described.

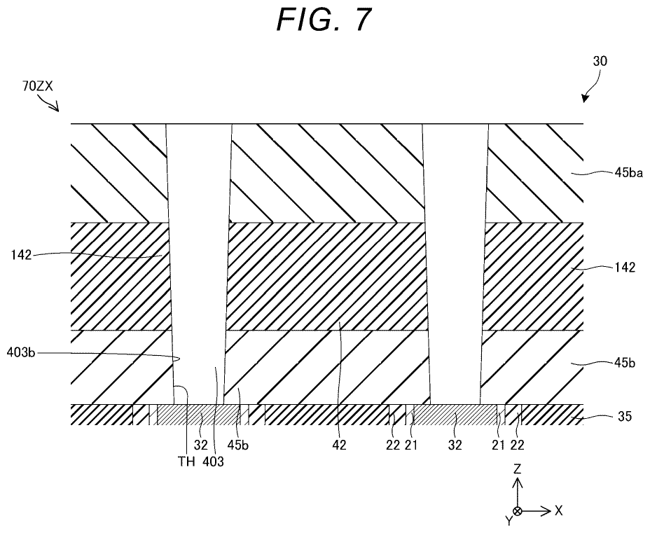

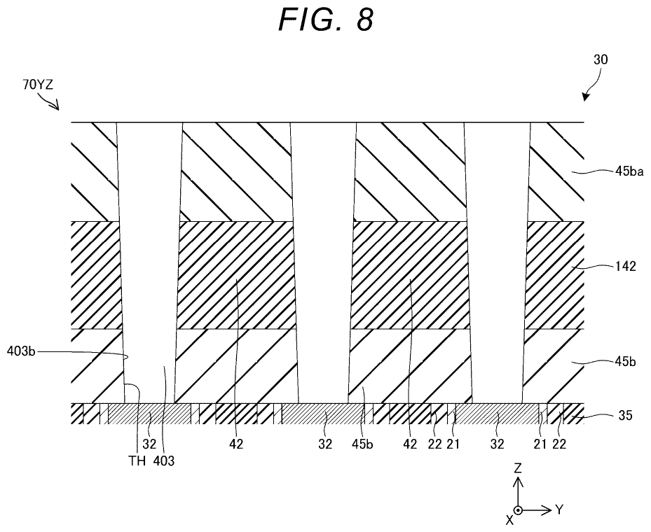

Firstly, as shown in FIGS. 7 and 8, an insulating film 45b, an insulating film 142, and an insulating film 45ba are provided in that order above an insulating layer 35. The insulating film 45b, the insulating film 142, and the insulating film 45ba extend in a plane approximately parallel to the XY plane. The insulating film 142 is, for example, a nitride of silicon. A transistor hole TH, which extends approximately parallel to the Z axis and penetrates the insulating film 45ba, the insulating film 142, and the insulating film 45b, is formed and then cleaned. The lower electrode 32 is exposed in a bottom of the transistor hole TH.

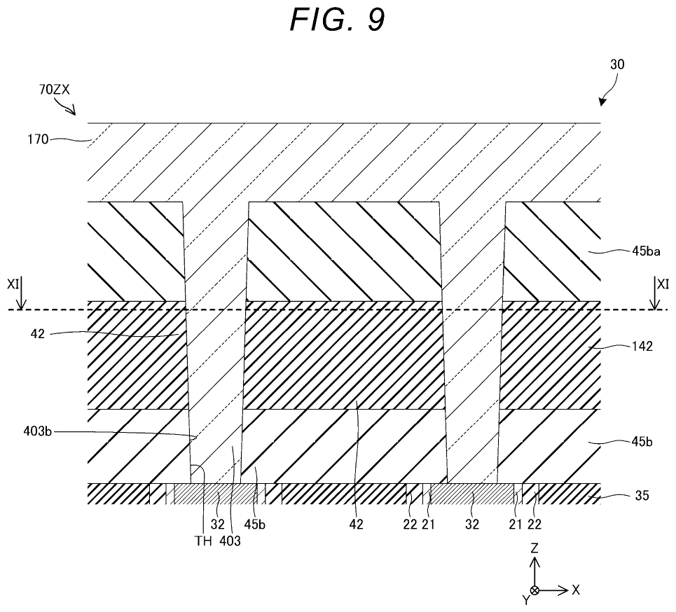

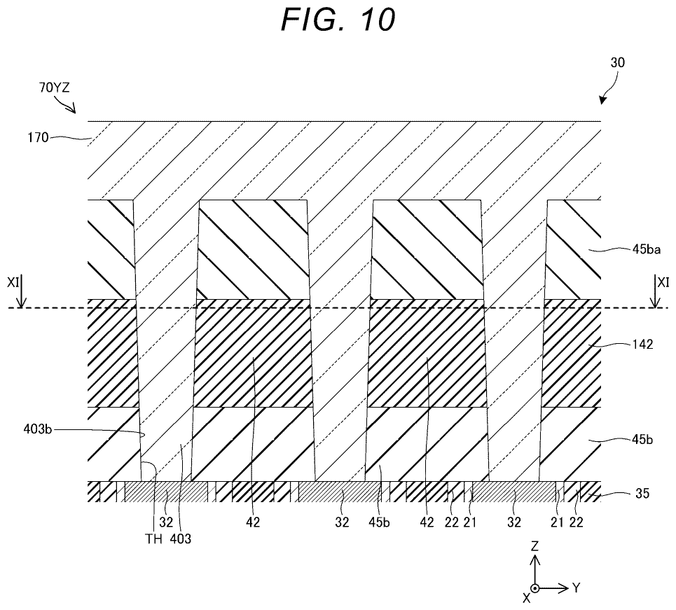

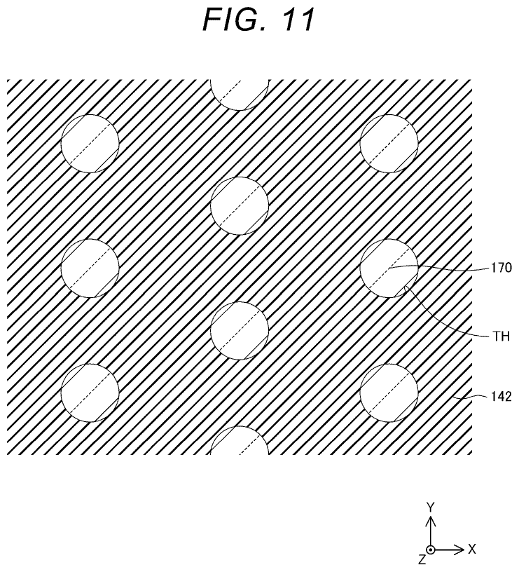

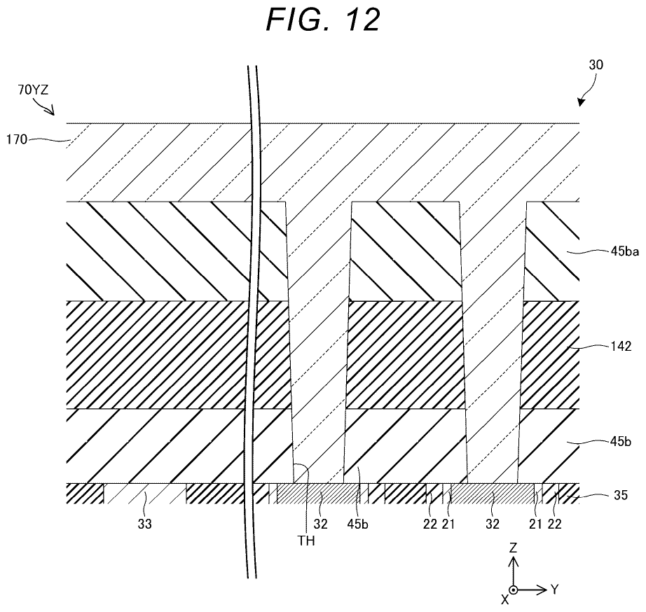

Next, as shown in FIGS. 9 to 12, a sacrificial amorphous silicon layer 170 is formed above the semiconductor device 30. Because of this, the transistor hole TH is filled with the sacrificial amorphous silicon layer 170.

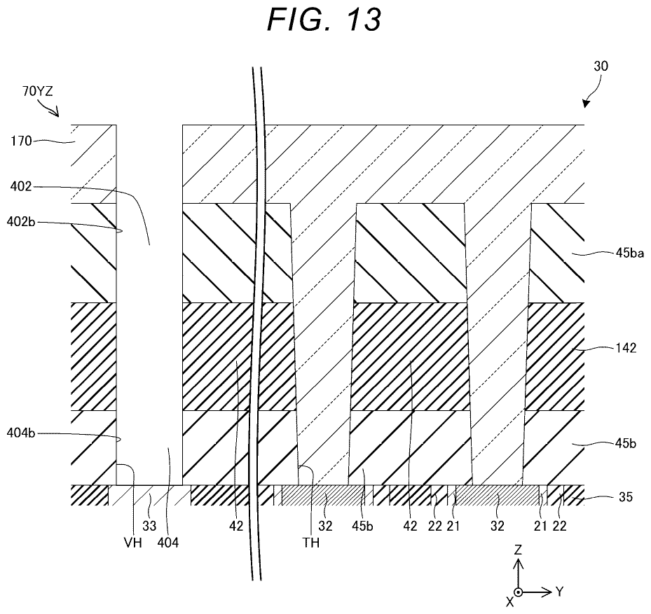

Next, as shown in FIG. 13, a mask is formed by a film formation, a resist application, exposure, development, detachment, and the like being carried out on a surface of the semiconductor device 30 using a lithographic method, after which a via hole VH extending approximately parallel to the Z axis is formed by etching in the semiconductor device 30. Here, the via hole VH penetrates as far as the conductor 33 via the insulating film 45ba, the insulating film 142, and the insulating film 45b. Below the via hole VH is the hole portion 404 formed in the insulating film 45b.

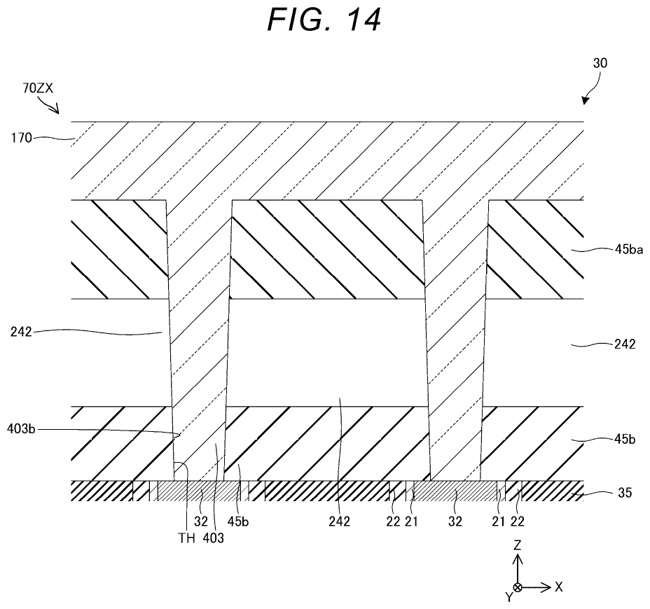

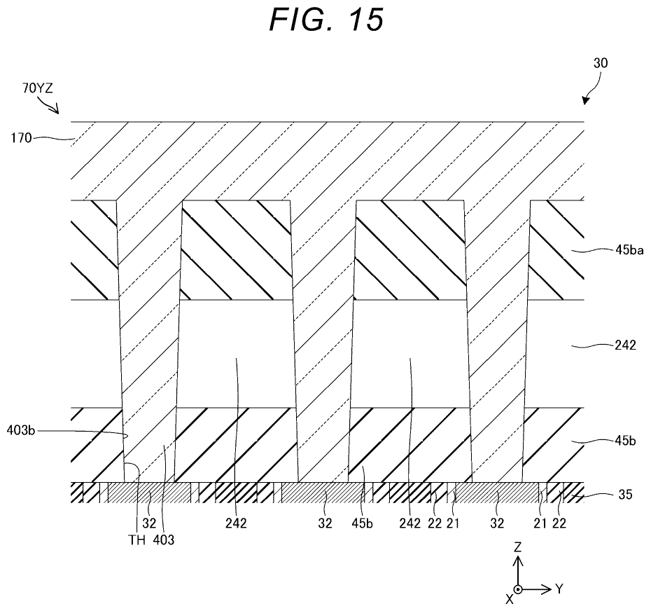

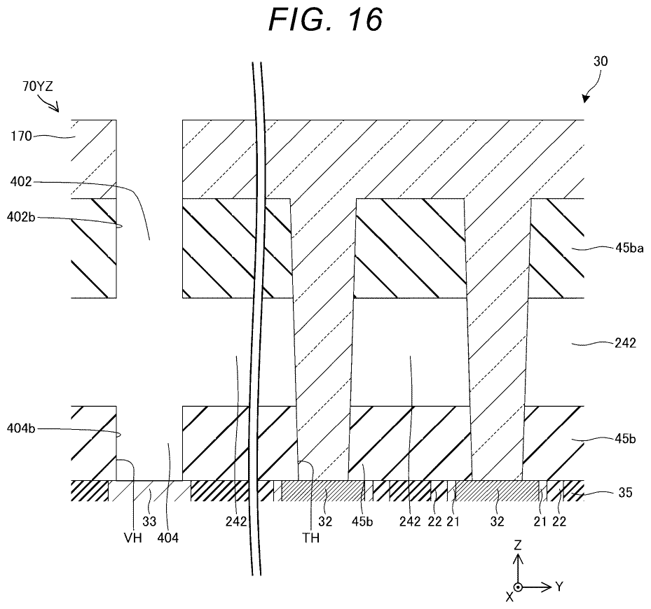

Next, as shown in FIGS. 14 to 16, the insulating film 142 in an interior of the via hole VH and the insulating film 142 between the insulating film 45ba and the insulating film 45b is removed by etching using a phosphoric acid solution, whereby a cavity 242 is formed.

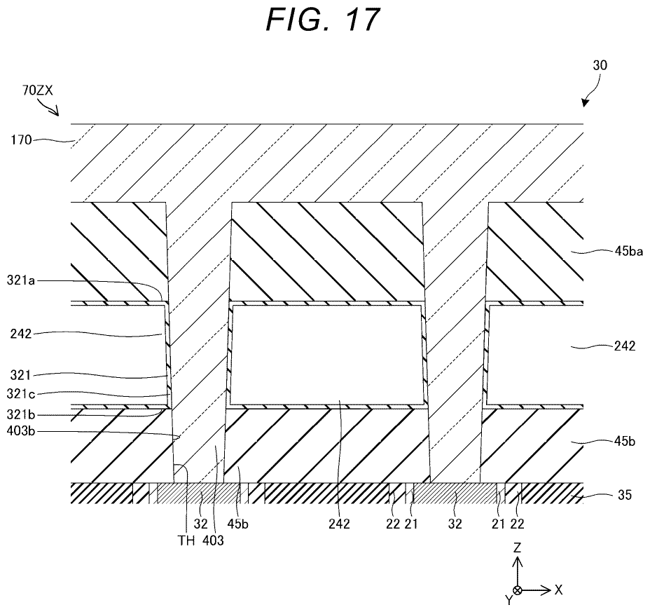

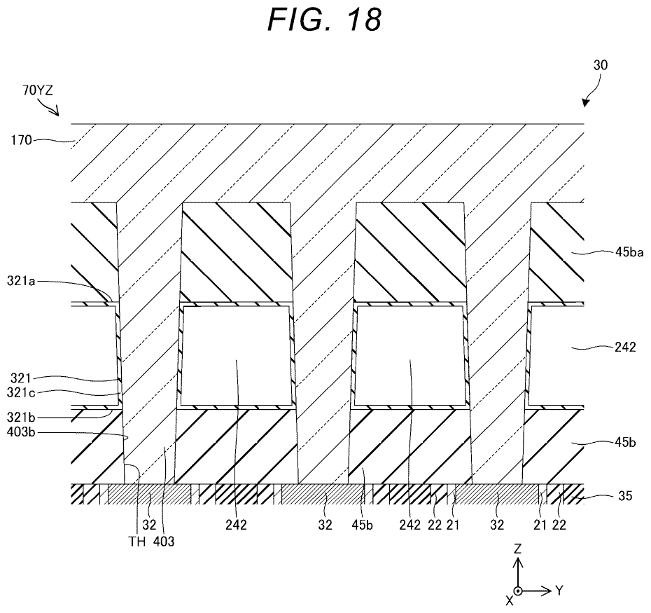

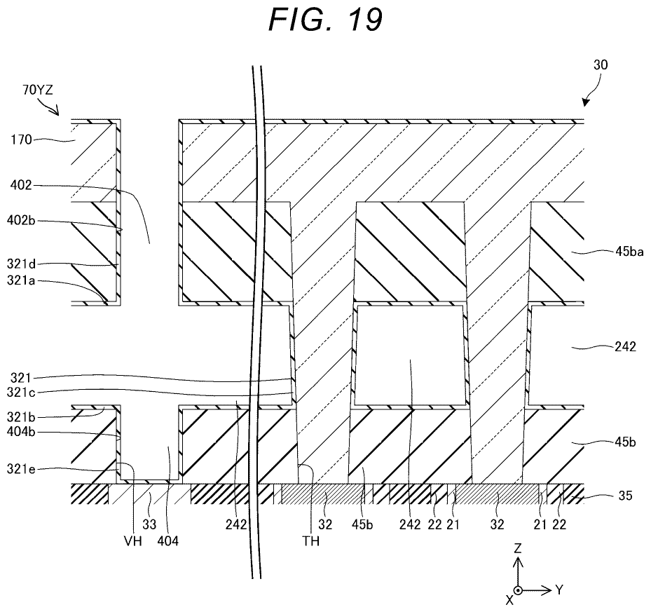

Next, as shown in FIGS. 17 to 19, the insulating film 321 is formed using, for example, atomic layer deposition. Specifically, the gate upper film portion 321a and the gate lower film portion 321b are formed on the lower face of the insulating film 45ba and an upper face of the insulating film 45b respectively. The gate insulating film portion 321c is formed in a periphery of the sacrificial amorphous silicon layer 170 exposed in the cavity 242. The via upper film portion 321d and the via lower film portion 321e are formed on the inner wall face 402b of the hole portion 402 and the inner wall face 404b of the hole portion 404 respectively.

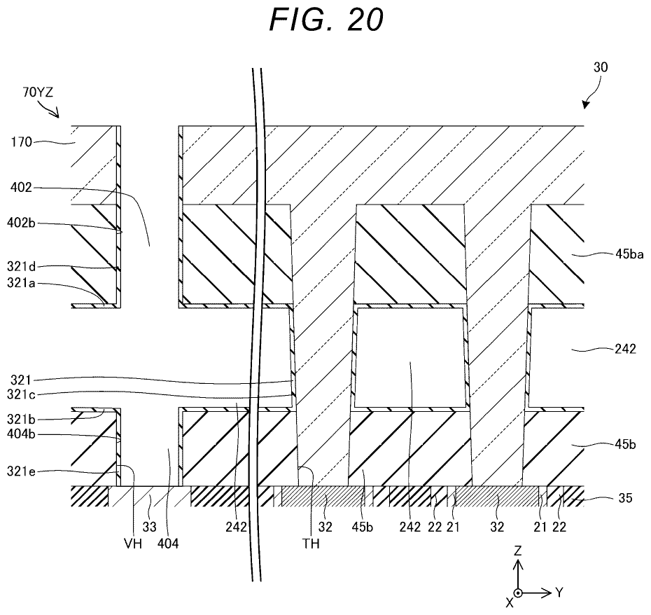

Next, as shown in FIG. 20, an upper portion of the semiconductor device 30 is etched back using reactive ion etching, whereby the conductor 33 in a bottom of the via hole VH is exposed.

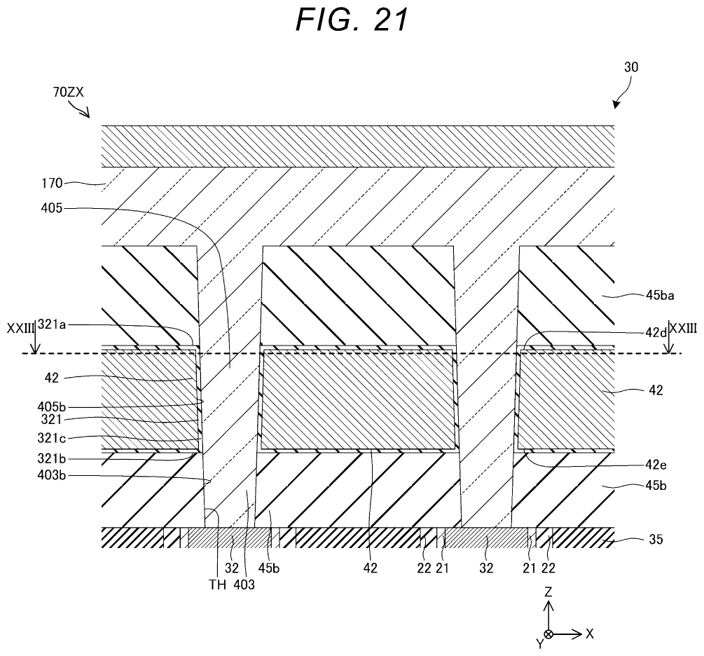

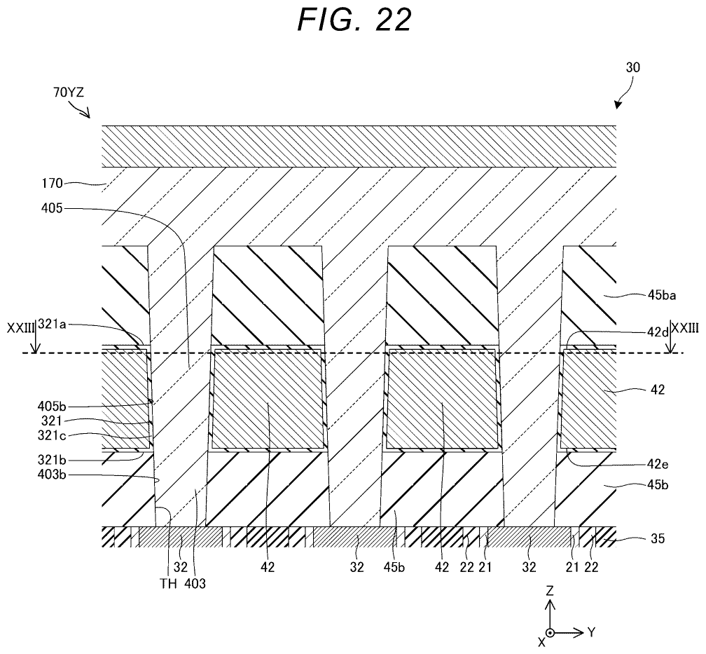

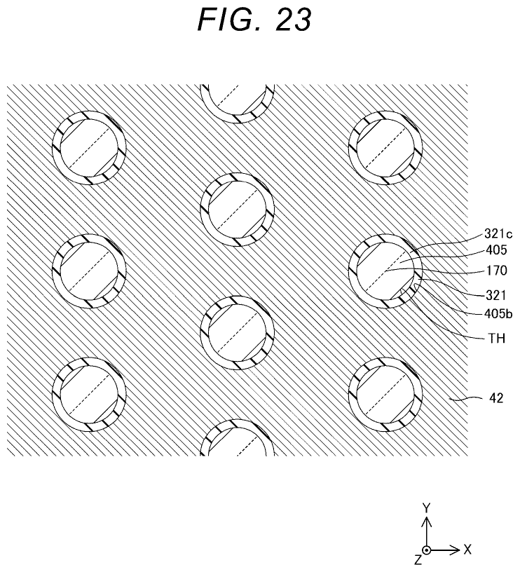

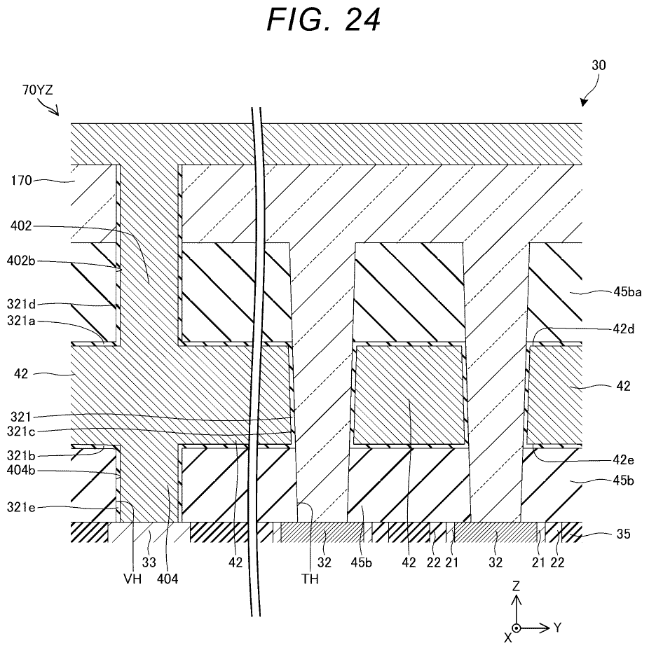

Next, as shown in FIGS. 21 to 24, the cavity 242 is filled with tungsten using a physical vapor deposition, whereby the conductive layer 42 is formed. Because of this, the conductive layer 42 and the conductor 33 come into contact, and are electrically connected.

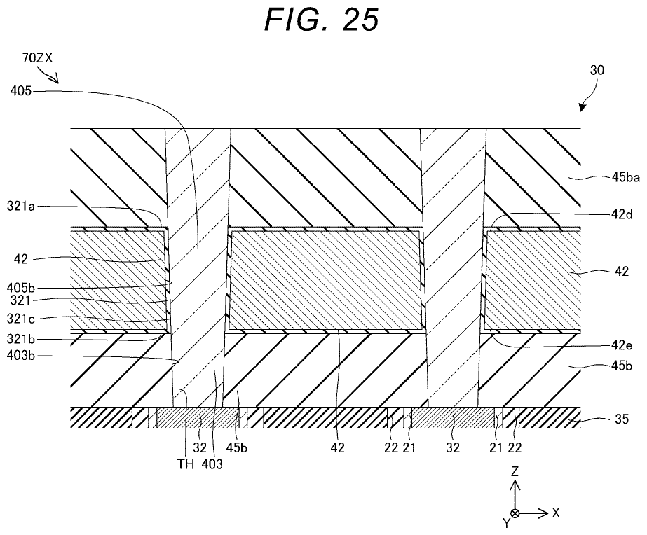

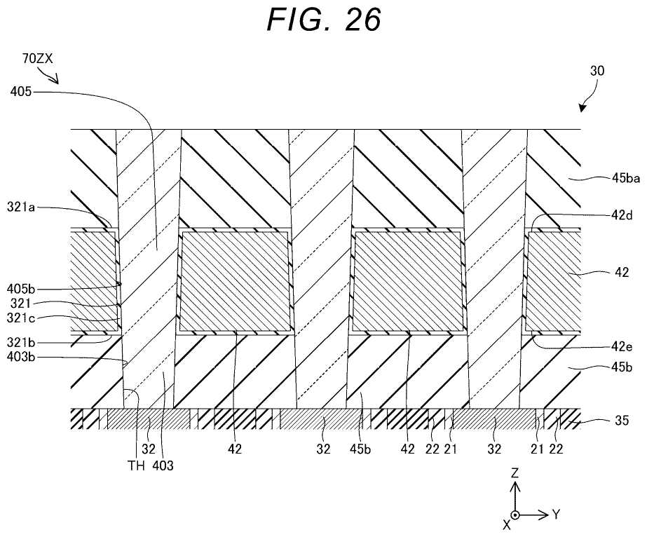

Next, as shown in FIGS. 25 and 26, the sacrificial amorphous silicon layer 170 is etched back, whereby an upper portion of the sacrificial amorphous silicon layer 170 is removed, and an upper face of the insulating layer 45ba is exposed. At this time, an upper end portion of the sacrificial amorphous silicon layer 170 is positioned, for example, above the conductive layer 42 in an interior of the transistor hole TH.

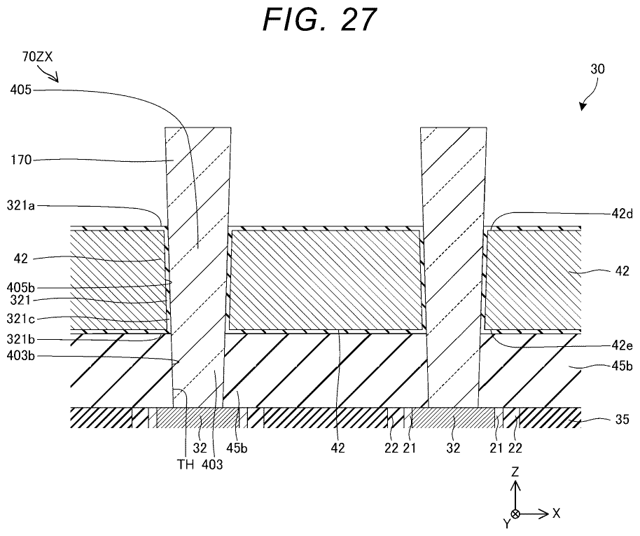

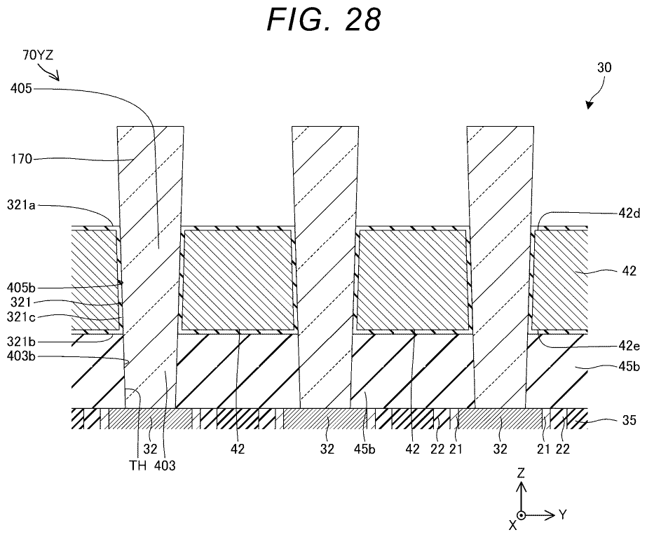

Next, as shown in FIGS. 27 and 28, the insulating layer 45ba is removed by being etched. Because of this, the gate upper film portion 321a is exposed.

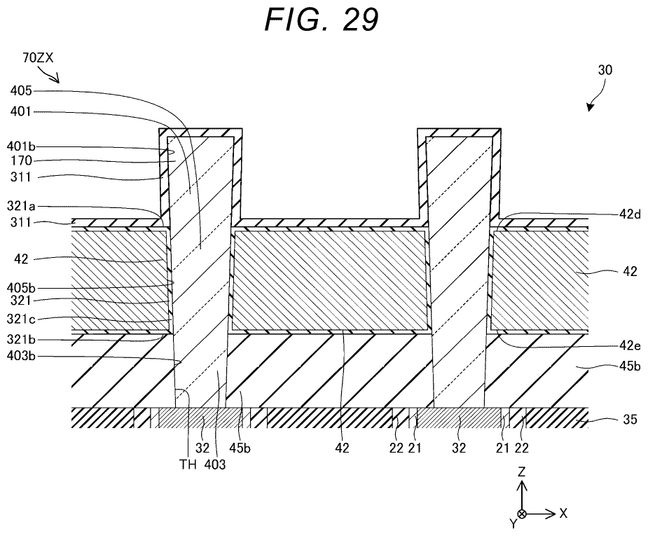

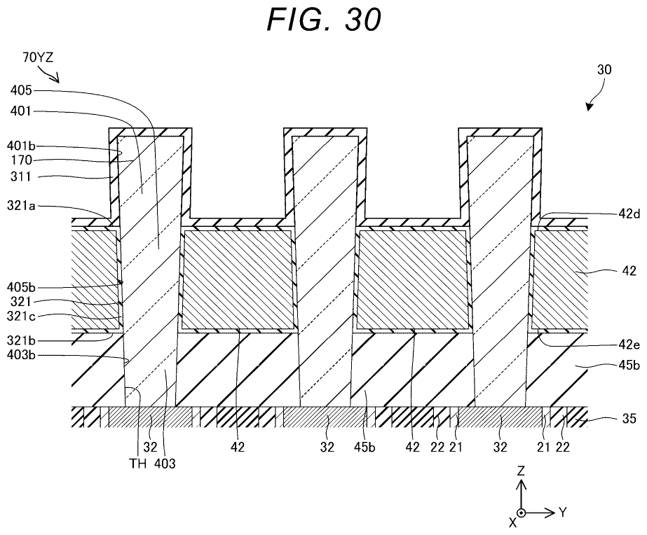

Next, as shown in FIGS. 29 and 30, the spacer film 311 is formed above the semiconductor device 30. Because of this, the sacrificial amorphous silicon layer 170 exposed above the gate upper film portion 321a and an upper face of the gate upper film portion 321a are covered by the spacer film 311.

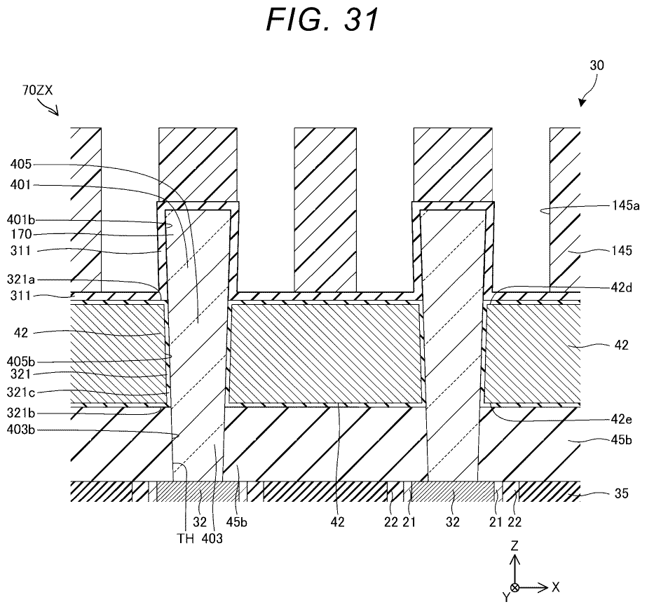

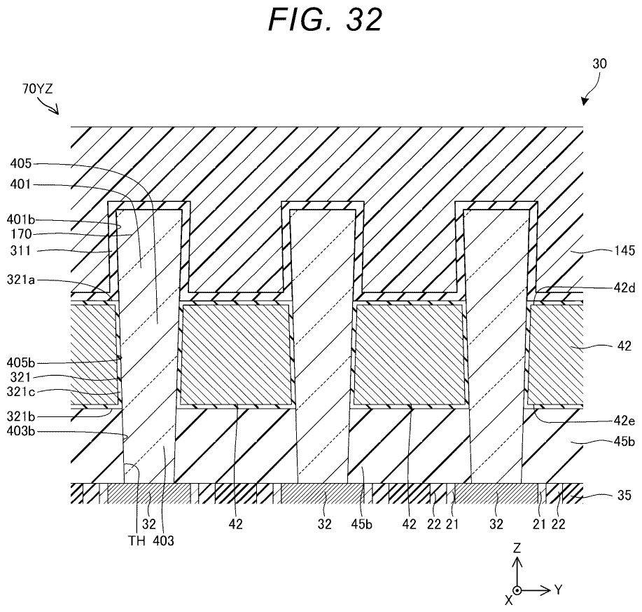

Next, as shown in FIGS. 31 and 32, a film formation, a resist application, exposure, development, detachment, and the like are carried out on the surface of the semiconductor device 30 using a lithographic method, whereby a mask layer 145 having a groove portion 145a that extends approximately parallel to the Y axis is formed.

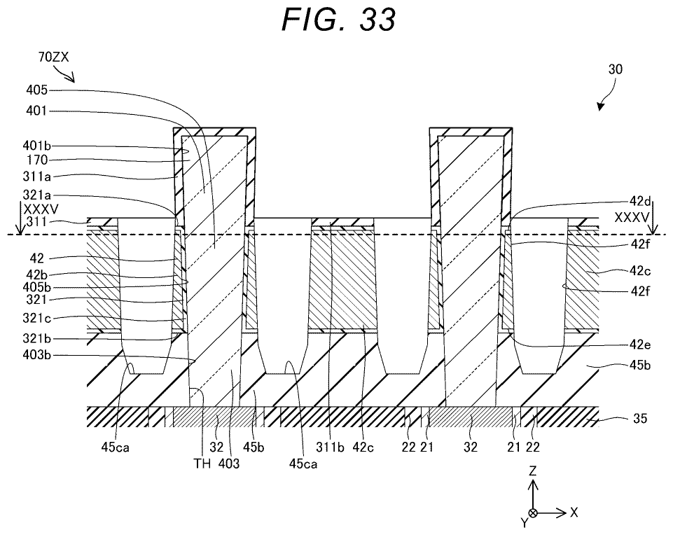

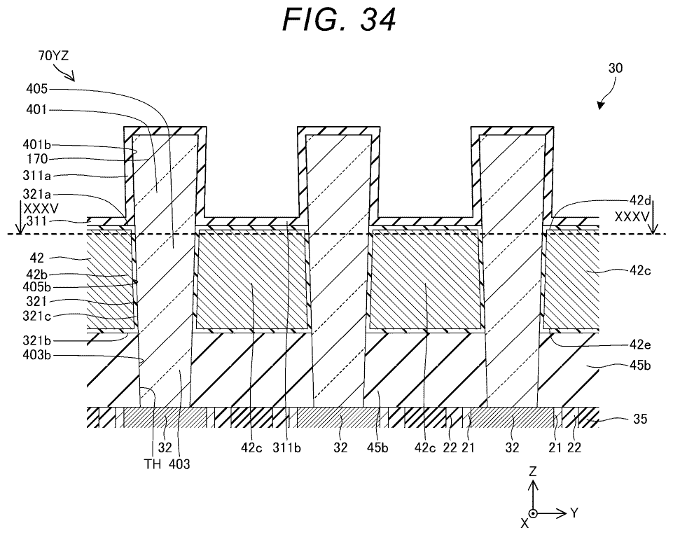

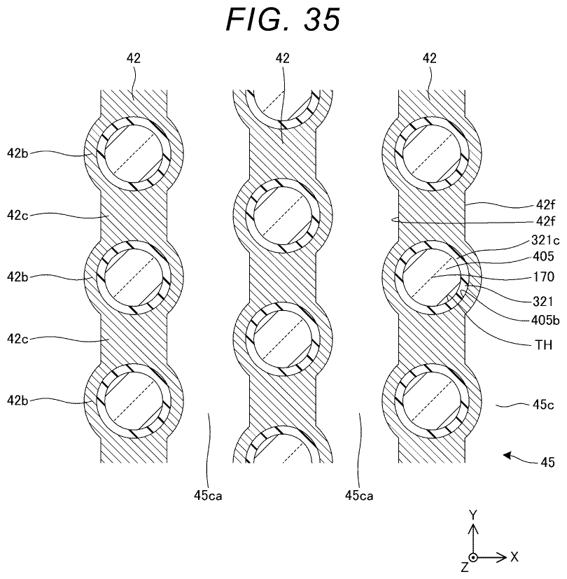

Next, as shown in FIGS. 33 to 35, a groove portion 45ca that penetrates as far as the insulating film 45b and extends approximately parallel to the Y axis is formed by etching in the semiconductor device 30. Because of this, the spacer film 311 is divided into the cylindrical portion 311a and the plate-form portion 311b. Also, the conductive layer 42 is divided into a plurality of electrodes that extend approximately parallel to the Y axis and are provided repeatedly in the X axis + direction. This electrode corresponds to the word line WL (refer to FIG. 1).

The enclosing portion 42b of the conductive layer 42 is formed by a self-alignment process. Specifically, even when there is a deviation in a position in which a mask is formed using a lithographic method, the cylindrical portion 311a of the spacer film 311 positioned on a side face of the sacrificial amorphous silicon layer 170 functions as a mask, meaning that the enclosing portion 42b is formed by self-alignment in a periphery of the transistor hole TH.

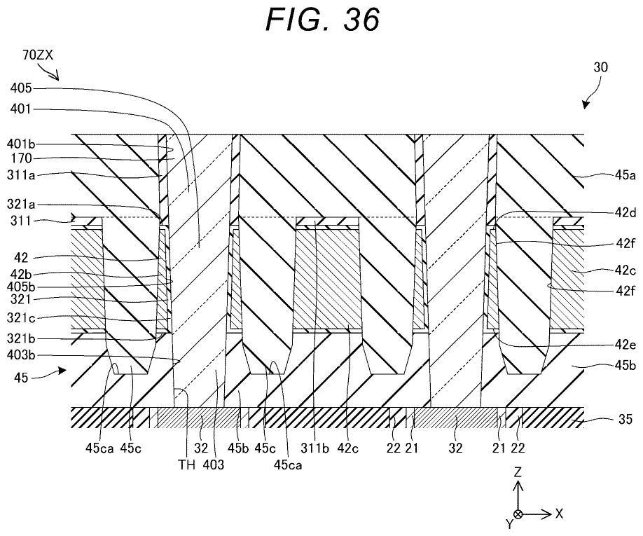

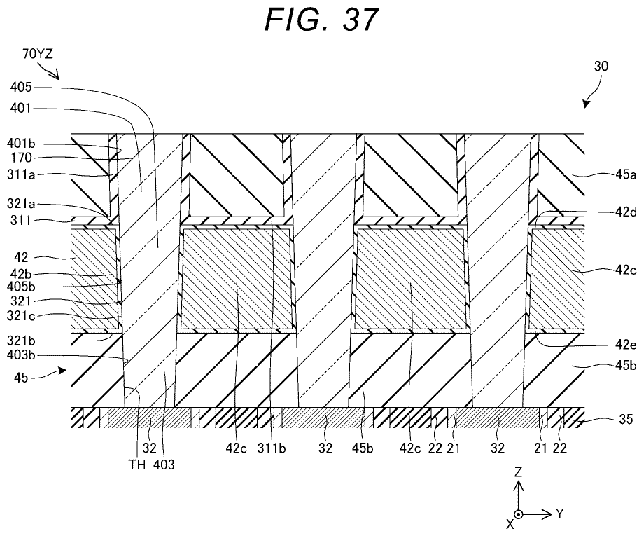

Next, as shown in FIGS. 36 and 37, the insulating films 45c and 45a are integrally formed above the semiconductor device 30. Further, a chemical mechanical polishing is carried out on an upper face of the semiconductor device 30, whereby an upper face of the sacrificial amorphous silicon layer 170 is exposed in the insulating film 45a.

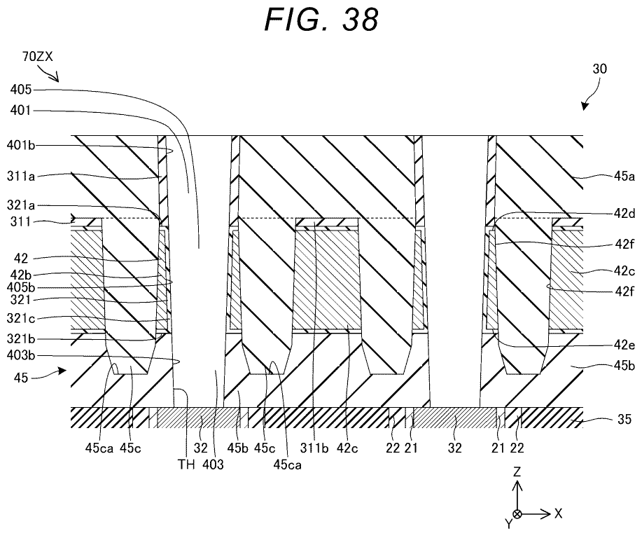

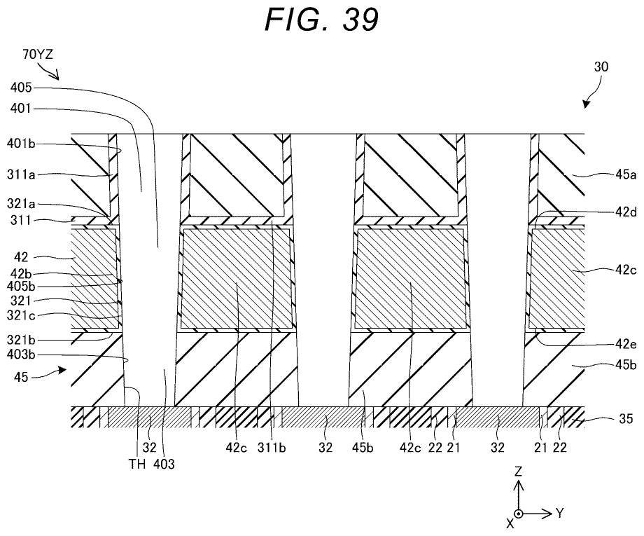

Next, as shown in FIGS. 38 and 39, the sacrificial amorphous silicon layer 170 in the interior of the transistor hole TH is removed by etching.

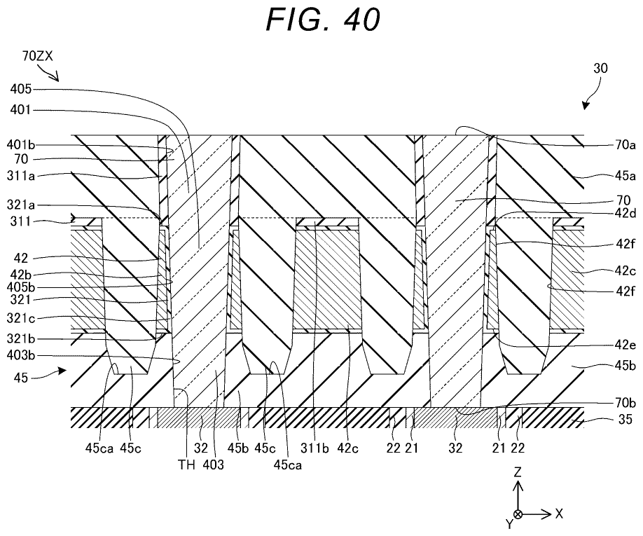

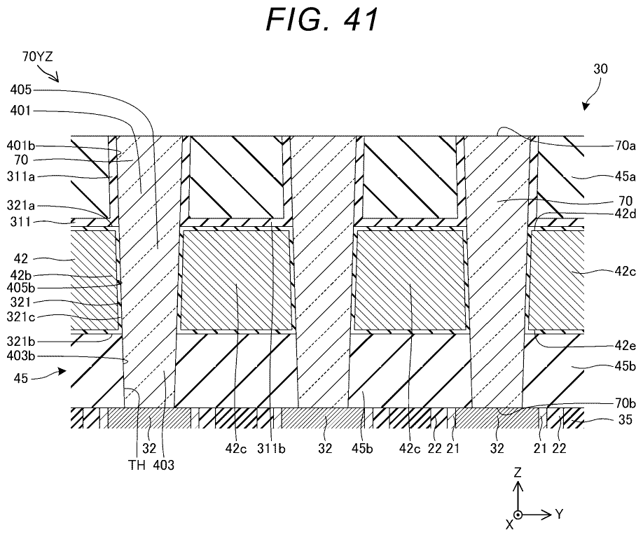

Next, as shown in FIGS. 40 and 41, the oxide semiconductor layer 70 is formed in the interior of the transistor hole TH. Further, a chemical mechanical polishing is carried out on the upper face of the semiconductor device 30.

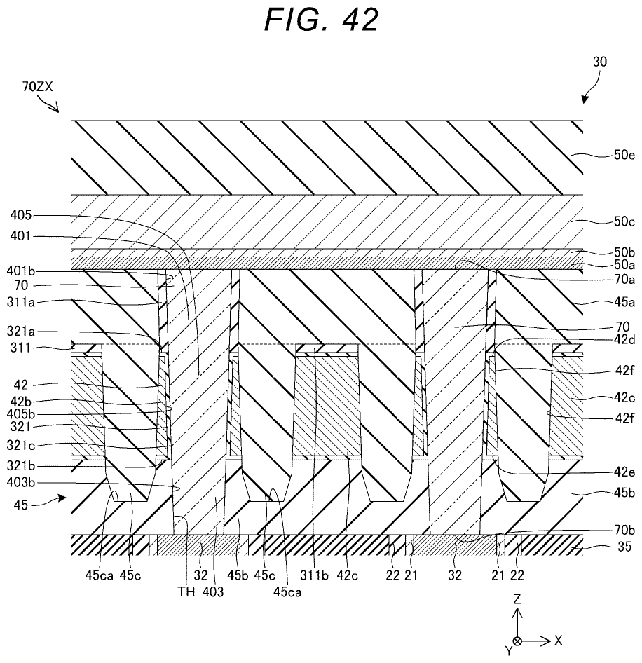

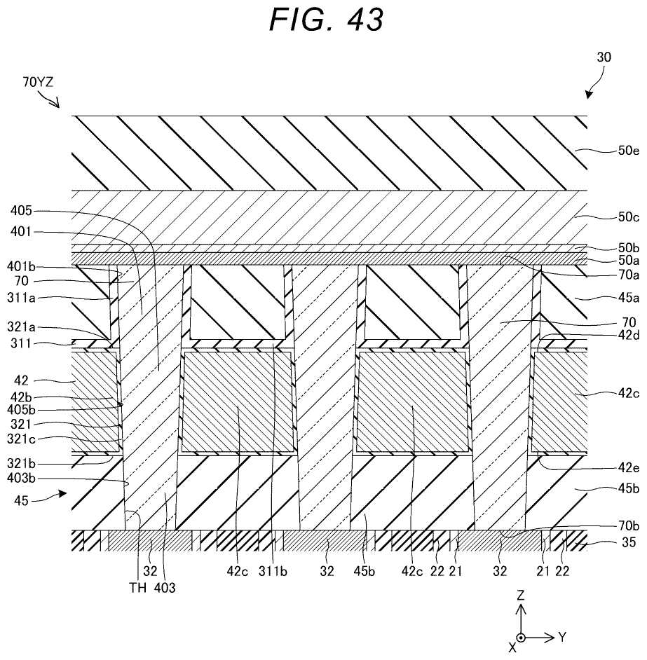

Next, as shown in FIGS. 42 and 43, the metal oxide layer 50a, the barrier metal layer 50b, and the metal film 50c are formed from down to up on the upper face of the semiconductor device 30. Further, a landing pad hard mask (LPHM) film 50e including, for example, an oxide of silicon is formed above the metal film 50c.

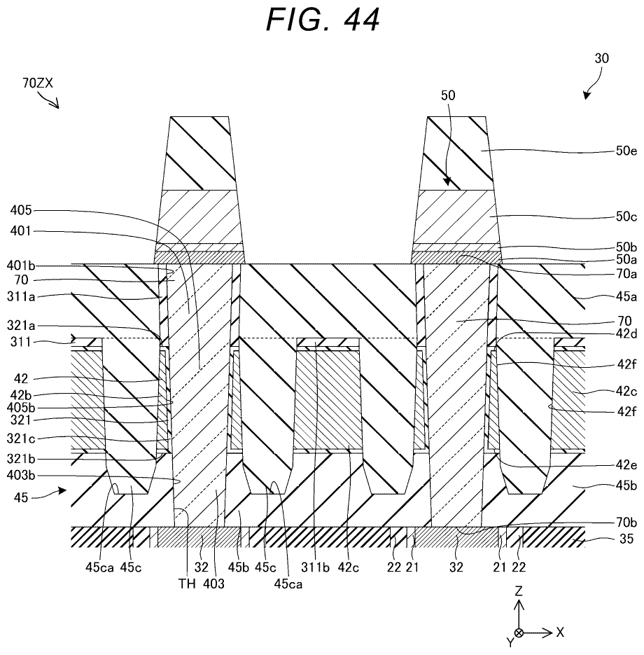

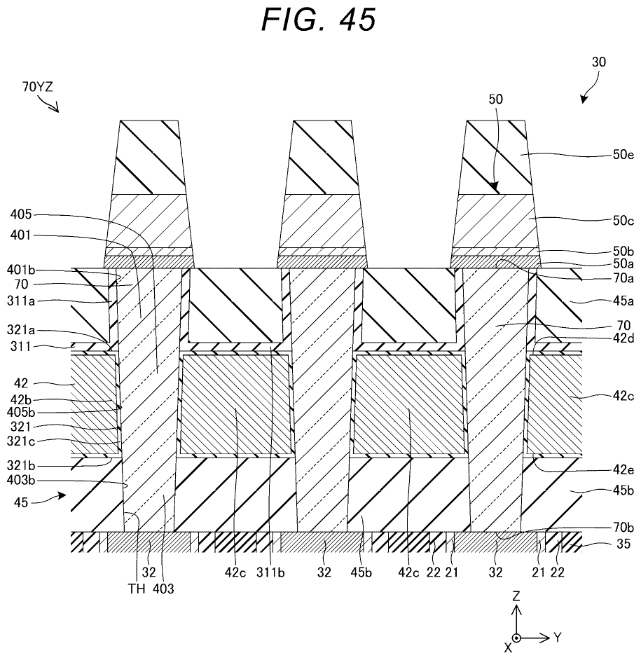

Next, as shown in FIGS. 44 and 45, a mask is formed by a film formation, a resist application, exposure, development, detachment, and the like being carried out on the surface of the semiconductor device 30 using a lithographic method, after which the upper electrode 50, which functions as a landing pad, is formed by etching in the semiconductor device 30. The upper electrode 50 includes the metal oxide layer 50a, the barrier metal layer 50b, and the metal film 50c.

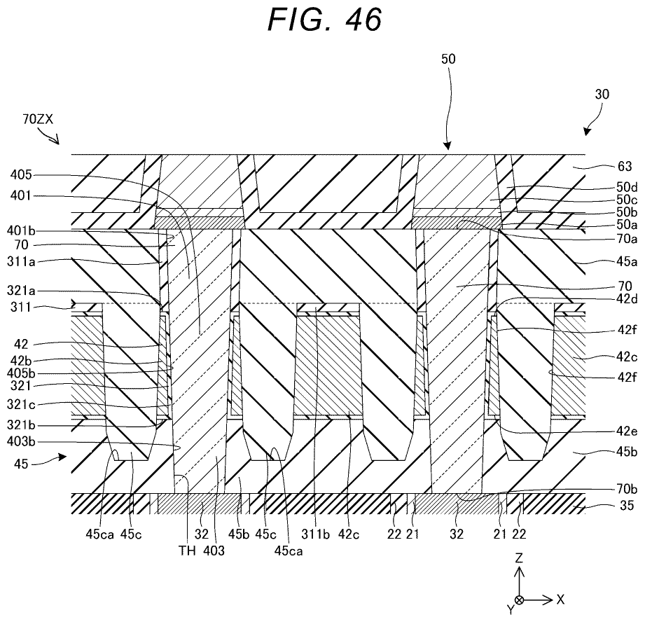

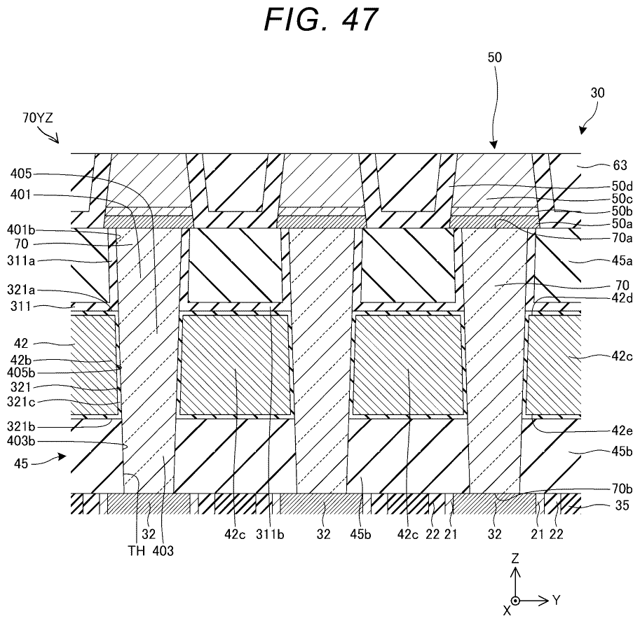

Next, as shown in FIGS. 46 and 47, an LP liner film 50d including, for example, an oxide of silicon is formed on the upper face of the semiconductor device 30. An insulating layer 63 that fills a gap caused by the LP liner film 50d is formed above the LP liner film 50d. The insulating layer 63 includes, for example, an oxide of silicon. Further, a chemical mechanical polishing is carried out on the upper face of the semiconductor device 30.

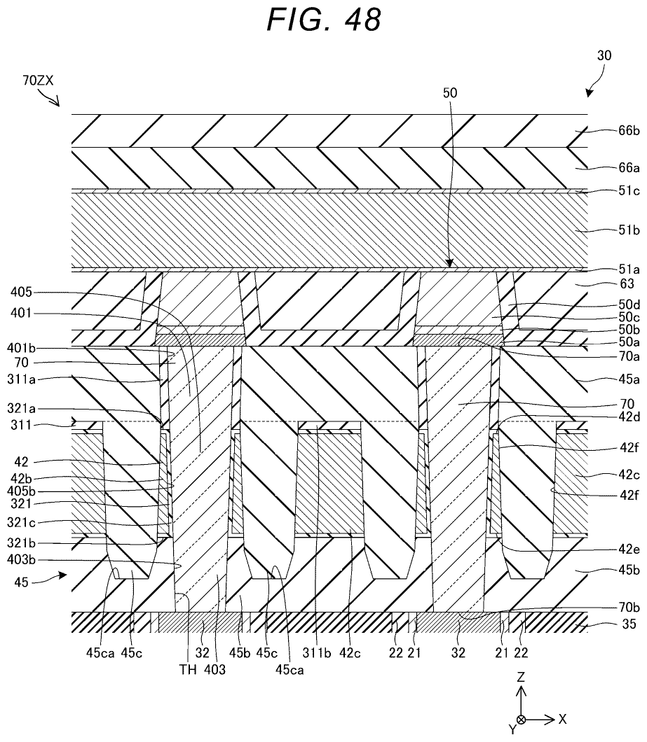

Next, as shown in FIGS. 48 and 49, a barrier metal layer 51a, a conductive layer 51b, and a barrier metal layer 51c are formed from down to up on the upper face of the semiconductor device 30. The barrier metal layers 51a and 51c include, for example, titanium nitride. The conductive layer 51b includes, for example, tungsten.

Further, bit line hard mask (BLHM) films 66a and 66b are formed from down to up on an upper face of the barrier metal layer 51c. The BLHM films 66a and 66b include, for example, a nitride of silicon and an oxide of silicon respectively.

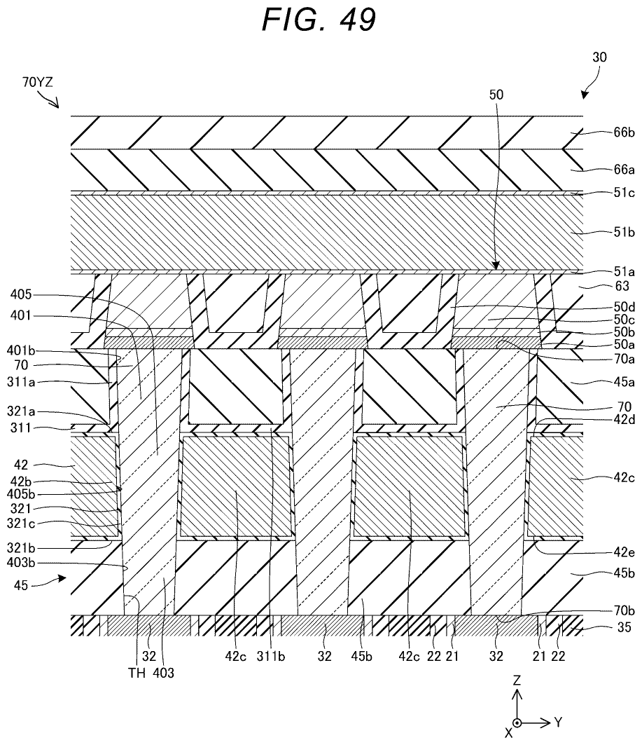

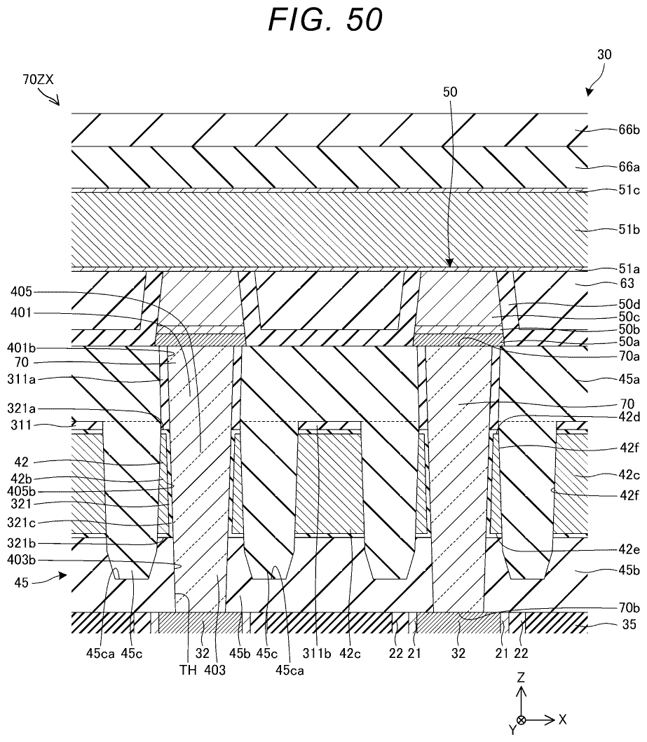

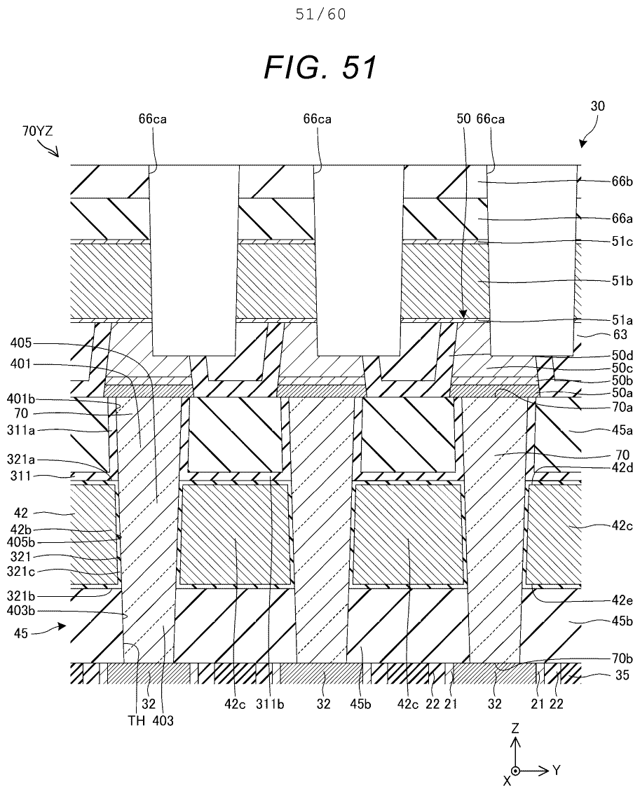

Next, as shown in FIGS. 50 and 51, a mask is formed by a film formation, a resist application, exposure, development, detachment, and the like being carried out on the surface of the semiconductor device 30 using a lithographic method, after which a groove portion 66ca that penetrates as far as the insulating layer 63 and the metal film 50c and extends approximately parallel to the X axis is formed by etching in the semiconductor device 30. Because of this, the barrier metal layer 51a, the conductive layer 51b, and the barrier metal layer 51c extend approximately parallel to the X axis, and are divided into electrodes provided repeatedly in the Y axis + direction. This electrode corresponds to the bit line BL (refer to FIG. 1).

Next, as shown in FIGS. 3 and 4, an insulating film 66c that fills the groove portion 66ca is formed above the semiconductor device 30. The insulating film 66c includes, for example, an oxide of silicon.

### Advantages

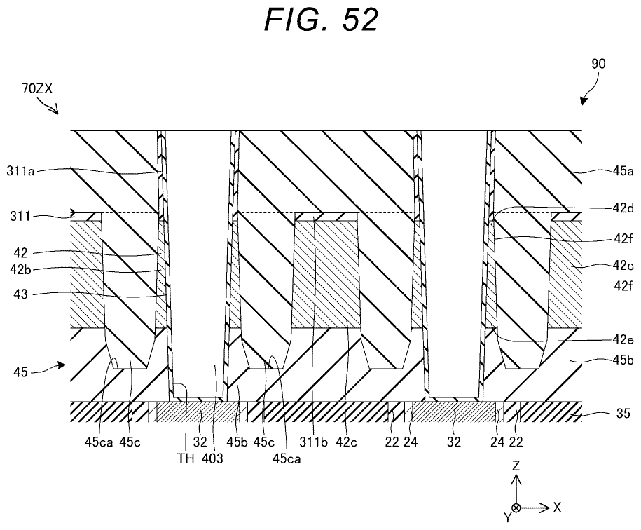

The gate insulating film 43 may be provided on an inner face of the transistor hole TH instead of the insulating film 321, as is the case in a semiconductor device 90 of a comparative example shown in FIG. 52.

For example, during a process of causing the lower electrode 32 to be exposed by etching back a bottom portion of the gate insulating film 43 using reactive ion etching, it may happen that the bottom portion of the gate insulating film 43 cannot be completely removed, meaning that one portion remains. This is liable to occur when a dielectric constant of the gate insulating film 43 is high.

In this case, a sufficient on-state current cannot be obtained. Also, an area of contact between the oxide semiconductor layer 70 and the lower electrode 32 varies, and gate leakage increases, meaning that reliability decreases.

Also, when forming the gate insulating film 43 in the transistor hole TH, the gate insulating film 43 is formed in state in which the lower electrode 32 is exposed. This means that when a state of high temperature is reached owing to heating, the ITO of the lower electrode 32 may be lost due to the rise in temperature.

According to the semiconductor device 30 described above, no process of etching back the bottom portion of the gate insulating film 43 using reactive ion etching is ever implemented, meaning that a state in which one portion of the bottom portion of the gate insulating film 43 remains can be prevented.

Also, the insulating film 321 is formed in a state in which exposure of the lower electrode 32 is prevented by the sacrificial amorphous silicon layer 170, because of which loss of the lower electrode 32 can be restricted.

Also, owing to a configuration in which the gate upper film portion 321a encloses the whole periphery of the central portion separated from the upper end 70a and the lower end 70b of the oxide semiconductor layer 70, and the spacer film 311 and the insulating film 45b enclose an upper portion (hereinafter also referred to as the semiconductor upper portion hereafter) and a lower portion (hereinafter also referred to as the semiconductor lower portion hereafter) of the oxide semiconductor layer 70 respectively, oxygen permeability in the semiconductor upper portion and the semiconductor lower portion can be restricted from differing greatly.

Because of this, amounts of oxygen in the semiconductor upper portion and the semiconductor lower portion can be more balanced, meaning that a resistance value of the semiconductor upper portion and a resistance value of the semiconductor lower portion can be brought closer together. Because of this, balanced on-state currents can be obtained, even when interchanging the source and the drain.

Also, a dielectric constant of a substance between the conductive layer 42 and the semiconductor upper portion and a dielectric constant of a substance between the conductive layer 42 and the semiconductor lower portion can be brought closer together, meaning that a fringe field between the conductive layer 42 and the semiconductor upper portion and a fringe field between the conductive layer 42 and the semiconductor lower portion can be restricted from differing greatly.

### Second Embodiment

A semiconductor device 30B according to a second embodiment will be described. From the second embodiment onward, a description of matters in common with the first embodiment will be omitted, and only differing points will be described. In particular, identical operational advantages resulting from identical configurations will not be referred to sequentially in each embodiment.

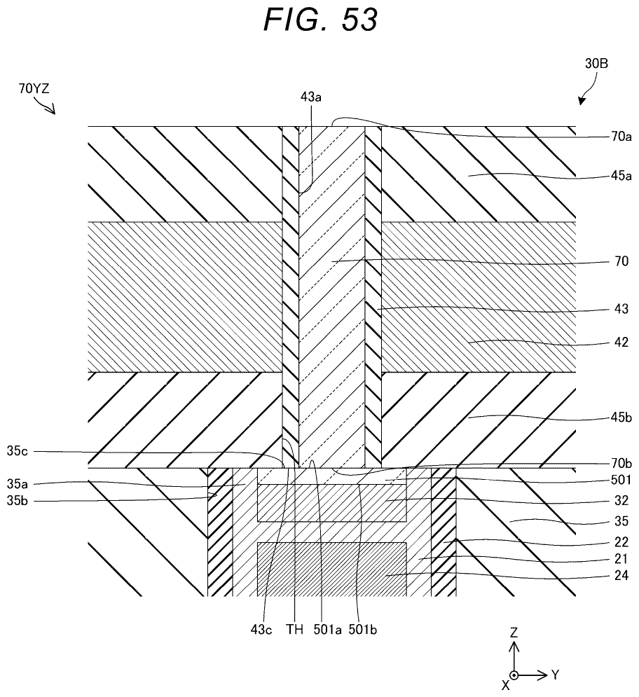

FIG. 53 is a cross-section 70YZ that is parallel to the YZ plane, and is a sectional view of the semiconductor device 30B when seen in the cross-section 70YZ in the oxide semiconductor layer 70.

As shown in FIG. 53, the semiconductor device 30B according to the second embodiment differs from the semiconductor device 30 shown in FIGS. 3 to 5 in including the gate insulating film 43 instead of the insulating film 321, and further including an interface film 501.

The gate insulating film 43 is of a tubular form having a hole portion 43a that extends in the up-down direction, and penetrates the insulating film 45a, the conductive layer 42, and the insulating film 45b. An outer peripheral face of the gate insulating film 43 is in contact with a whole periphery of an inner wall face of the transistor hole TH. In other words, the inner wall face of the transistor hole TH encloses a whole periphery of the gate insulating film 43.

An inner peripheral face of the gate insulating film 43 is in contact with a whole periphery of a side face of the oxide semiconductor layer 70. In other words, the gate insulating film 43 encloses a whole periphery of the side face of the oxide semiconductor layer 70.

The interface film 501 is provided between the oxide semiconductor layer 70 and the lower electrode 32, and is electrically connected to the oxide semiconductor layer 70 and the lower electrode 32. Here, the interface film 501 is provided between the oxide semiconductor layer 70 and insulating film 45b and the lower electrode 32.

Specifically, a hole portion 35a is formed extending in the up-down direction in the insulating layer 35. The interface film 501 is provided in an interior of the hole portion 35a, and is of a flattened columnar form. The interface film 501 is exposed in the insulating layer 35. Specifically, an upper face 501a of the interface film 501 is exposed in an aperture portion 35c of the hole portion 35a, and is in contact with the lower end 70b of the oxide semiconductor layer 70, the lower end portion 43c of the gate insulating film 43, and a lower face of the insulating film 45b.

The lower electrode 32 has a cross-section of approximately the same form as that of the interface film 501, and is of a flattened columnar form. The lower electrode 32 is provided in an interior of the insulating layer 35, and is not exposed in the insulating layer 35. Specifically, the lower electrode 32 is provided in an interior of the hole portion 35a, and is not exposed in the aperture portion 35c. Here, the lower electrode 32 is provided below the interface film 501, and is in contact with a lower face 501b of the interface film 501. The lower electrode 32 opposes the capacitor electrode 24 provided below across the conductor 21.

An area of contact between the lower face 501b of the interface film 501 and the lower electrode 32 (hereinafter referred to the lower contact area) is greater than an area of contact between the lower end 70b of the oxide semiconductor layer 70 and the upper face 501a of the interface film 501 (hereinafter referred to as the upper contact area).

Side faces of the interface film 501, the lower electrode 32, and the capacitor electrode 24 are enclosed by the conductor 21. The insulating film 22 encloses the conductor 21. An upper outer peripheral face of the insulating film 22 is in contact with a whole periphery of an inner wall face 35b of the hole portion 35a.

The interface film 501 is formed of a semiconductor or a conductor, and contains atoms whose binding energy with oxygen atoms is greater than binding energy between oxygen atoms and indium atoms in the lower electrode 32.

The interface film 510 includes, for example, gallium. The interface film 501 is, for example, an oxide semiconductor. Specifically, the interface film 510 includes indium, gallium, zinc, and oxygen. More specifically, the interface film 510 is IGZO. The interface film 501 may also be IGO, IZO, GZO, InO, ZnO, GaO, SnO, or the like.

A composition ratio of indium, gallium, and zinc in the oxide semiconductor layer 70 differs from a composition ratio of indium, gallium, and zinc in the interface film 501.

### Semiconductor Device Manufacturing Method

Hereafter, a method of manufacturing the semiconductor device 30B will be described.

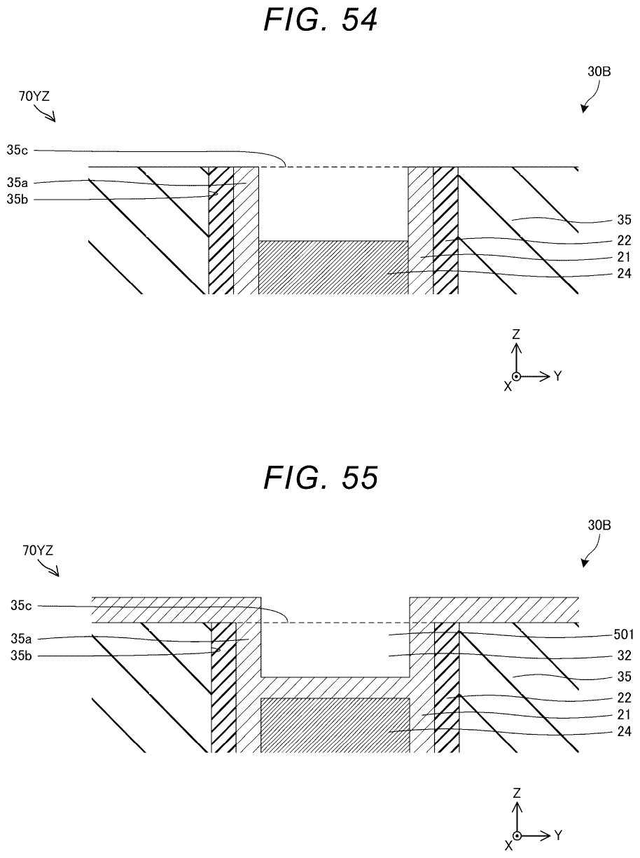

Firstly, as shown in FIG. 54, the hole portion 35a is formed in the insulating layer 35. The insulating film 22, the conductor 21, and the capacitor electrode 24 are formed in the interior of the hole portion 35a.

Next, as shown in FIG. 55, the conductor 21 is further formed above the semiconductor device 30B. The conductor 21 functions as, for example, a barrier film.

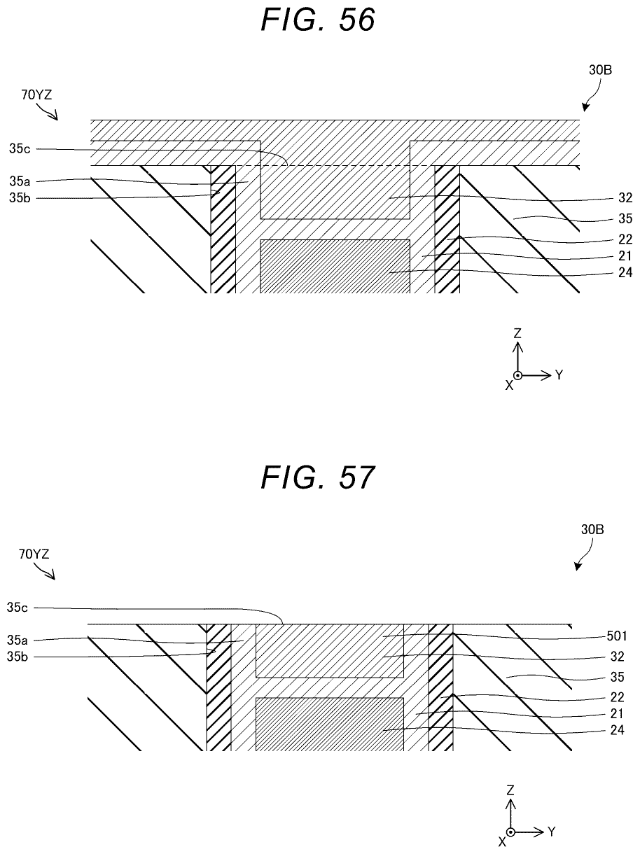

Next, as shown in FIG. 56, the lower electrode 32 is formed above the semiconductor device 30B.

Next, as shown in FIG. 57, a chemical mechanical polishing is carried out on an upper face of the semiconductor device 30B, whereby the lower electrode 32 is exposed in the aperture portion 35c.

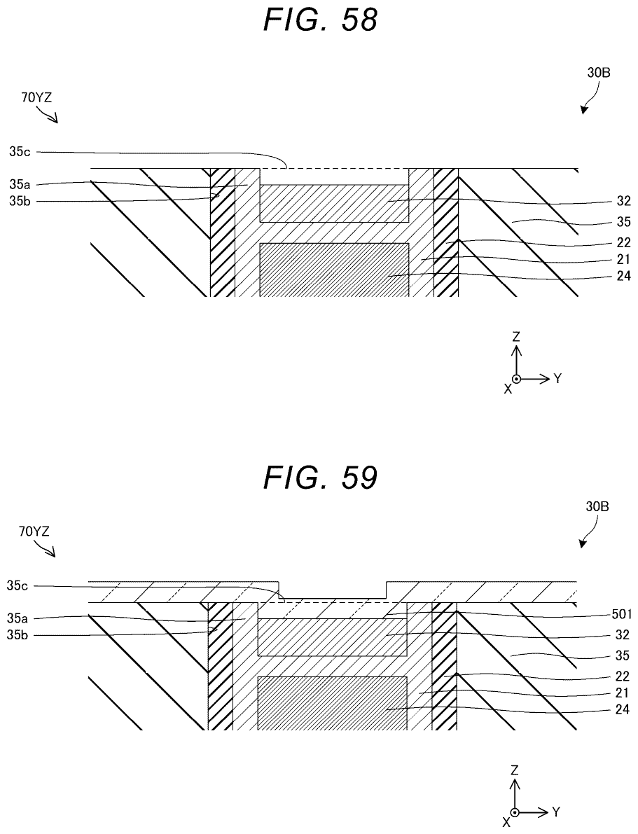

Next, as shown in FIG. 58, an upper face of the lower electrode 32 is lowered using wet etching in such a way that the lower electrode 32 is not exposed in the aperture portion 35c.

Next, as shown in FIG. 59, the interface film 501 is formed above the semiconductor device 30B.

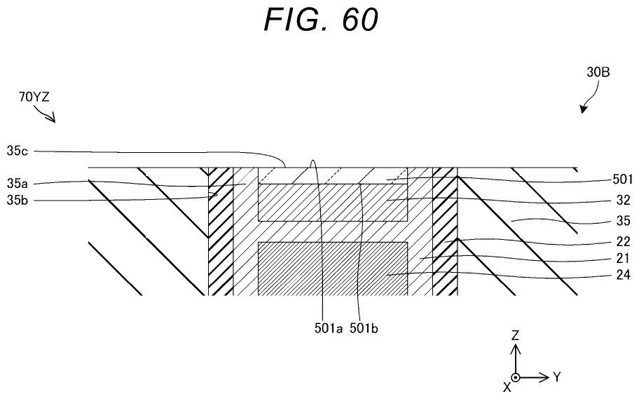

Next, as shown in FIG. 60, a chemical mechanical polishing is carried out on the upper face of the semiconductor device 30B, whereby the upper face 501a of the interface film 501 is exposed in the aperture portion 35c of the hole portion 35a.

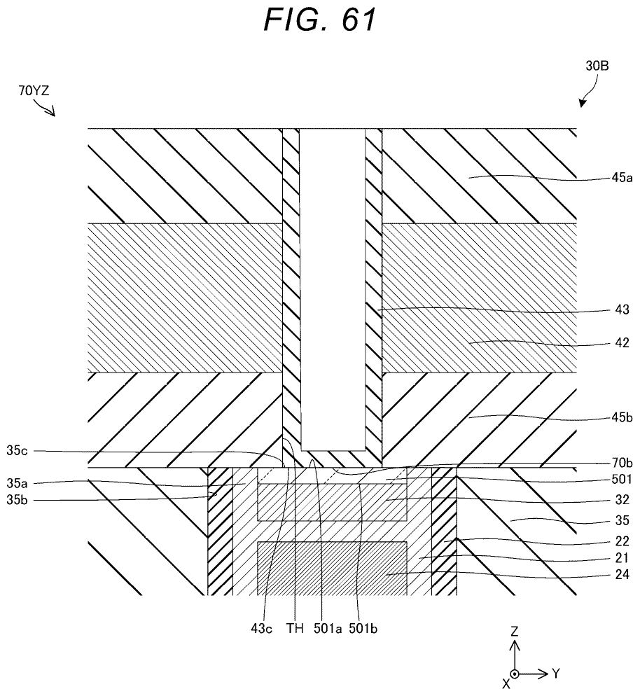

Next, as shown in FIG. 61, the insulating film 45b, the insulating layer 42, and the insulating film 45a are provided in that order above the insulating layer 35. The transistor hole TH, which extends approximately parallel to the Z axis and penetrates the insulating film 45b, the insulating layer 42, and the insulating film 45a, is formed and then cleaned. The gate insulating film 43 is formed on the inner face of the transistor hole TH. At this time, the gate insulating film 43 is formed by heating, meaning that the ITO of the lower electrode 32 may be lost due to the rise in temperature.

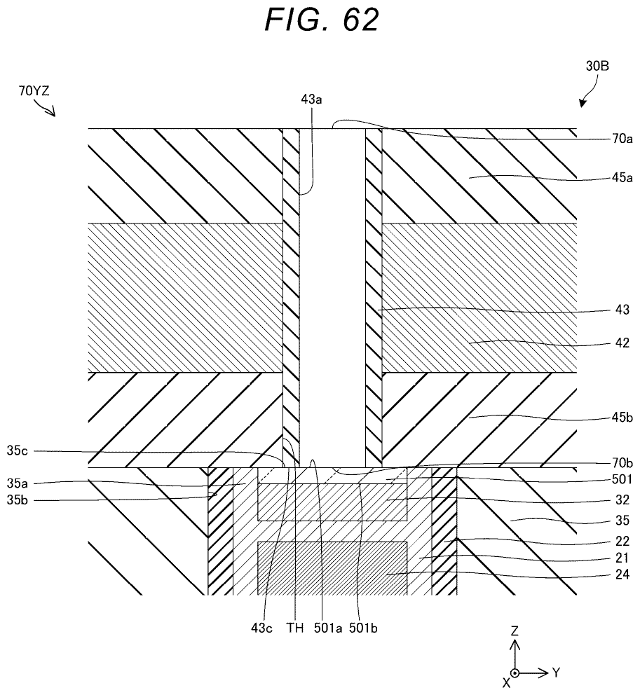

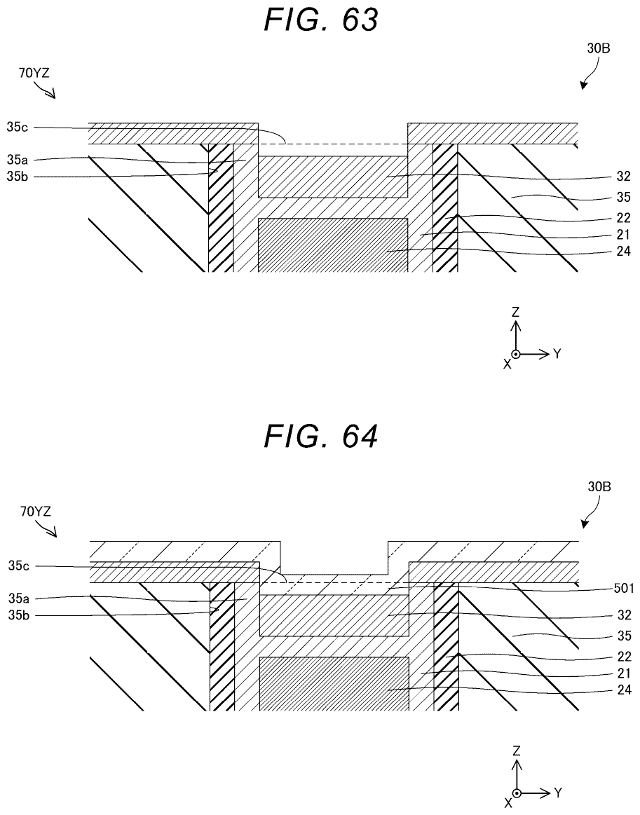

Next, as shown in FIG. 62, the bottom portion of the gate insulating film 43 is etched back using reactive ion etching, whereby the interface film 501 in a bottom portion of the transistor hole TH is exposed.

Next, as shown in FIG. 53, the oxide semiconductor layer 70 is formed in the interior of the transistor hole TH. Further, a chemical mechanical polishing is carried out on the upper face of the semiconductor device 30B.

The semiconductor device 30B shown in FIG. 56 is such that the conductor 21 does not remain in the interior of the hole portion 35a, but protrudes from the aperture portion 35c to an exterior of the hole portion 35a, where the conductor 21 is formed. Meanwhile, when the conductor 21 is formed remaining in the interior of the hole portion 35a, as shown in FIG. 63, the process of chemical mechanical polishing shown in FIG. 57 and the process of wet etching shown in FIG. 58 may be omitted, and the interface film 501 formed above the semiconductor device 30B.

### Advantages

For example, when a concentration of indium in the interface film 501 is greater than a concentration of indium in the oxide semiconductor layer 70, contact resistance between the oxide semiconductor layer 70 and the lower electrode 32 can be reduced.

When a concentration of zinc in the interface film 501 is greater than a concentration of zinc in the oxide semiconductor layer 70, the aforementioned contact resistance can be reduced. Also, when a concentration of gallium in the interface film 501 is lower than a concentration of gallium in the oxide semiconductor layer 70, the aforementioned contact resistance can be reduced. When the concentration of indium in the interface film 501 is greater than the concentration of indium in the oxide semiconductor layer 70, the aforementioned contact resistance can be effectively reduced.

Also, when the concentration of gallium in the interface film 501 is low and the concentration of zinc in the interface film 501 is high in comparison with those of the oxide semiconductor layer 70, the contact resistance between the oxide semiconductor layer 70 and the lower electrode 32 can be reduced.

Also, when, provisionally, the interface film 501 is not provided, the lower electrode 32 is exposed. Because of this, the ITO of the lower electrode 32 may be lost due to a rise in temperature when the gate insulating film 43 is formed by heating.

Bonding energy with oxygen decreases in the order of gallium, indium, and zinc. A configuration in which the interface film 501 including gallium is provided is such that the interface film 501 can be caused to function as a strong cover. Because of this, loss of the lower electrode 32 when forming the gate insulating film 43 can be restricted.

That is, when the concentration of gallium in the interface film 501 is greater than the concentration of gallium in the lower electrode 32, bonding energy between gallium and oxygen is high, because of which loss of the lower electrode 32 when forming the gate insulating film 43 can be restricted.

Also, a configuration in which the lower contact area is greater than the upper contact area is such that a contact area between ITO and IGZO can be increased, because of which contact resistance with the lower electrode 32 can be reduced.

Although a configuration in which the lower electrode 32 is physically in contact with the oxide semiconductor layer 70 in the semiconductor device 30 has been described, this is not limiting. Provided that a configuration is such that the lower electrode 32 is electrically connected to the oxide semiconductor layer 70, a configuration may be such that the lower electrode 32 is not physically in contact with the oxide semiconductor layer 70.

Also, although a configuration in which the upper electrode 50 is physically in contact with the oxide semiconductor layer 70 in the semiconductor device 30 has been described, this is not limiting. Provided that a configuration is such that the upper electrode 50 is electrically connected to the oxide semiconductor layer 70, a configuration may be such that the upper electrode 50 is not physically in contact with the oxide semiconductor layer 70.

Also, although a configuration in which the interface film 501 is physically in contact with the oxide semiconductor layer 70 in the semiconductor device 30B has been described, this is not limiting. Provided that a configuration is such that the interface film 501 is electrically connected to the oxide semiconductor layer 70, a configuration may be such that the interface film 501 is not physically in contact with the oxide semiconductor layer 70.

Also, although a configuration in which the interface film 501 is physically in contact with the lower electrode 32 in the semiconductor device 30B has been described, this is not limiting. Provided that a configuration is such that the interface film 501 is electrically connected to the lower electrode 32, a configuration may be such that the interface film 501 is not physically in contact with the lower electrode 32.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a substrate extending in a first direction;
a gate electrode extending along the first direction above the substrate;
an oxide semiconductor that extends in a second direction intersecting the first direction above the substrate and penetrates the gate electrode;
a first electrode electrically connected to one end of the oxide semiconductor;
a second electrode electrically connected to the other end of the oxide semiconductor; and
a first insulating film made of a first insulating material, wherein
the first insulating film includes:
a first film portion that covers an upper surface of the gate electrode,
a second film portion that covers a lower surface of the gate electrode, and
a third film portion that extends in the second direction between the gate electrode and the oxide semiconductor.

2. The semiconductor device according to claim 1, further comprising:
a second insulating film made of a second insulating material that is different from the first insulating material, wherein
the gate electrode has a side surface that contacts the second insulating film.

3. The semiconductor device according to claim 1, wherein
the first insulating material includes silicon and nitrogen.

4. The semiconductor device according to claim 1, further comprising:
a via electrode that extends along the second direction adjacent to the oxide semiconductor above the substrate;
a third insulating film that surrounds the oxide semiconductor and the via electrode above the first film portion of the first insulating film; and
a fourth insulating film that surrounds the oxide semiconductor and the via electrode below the second film portion.

5. The semiconductor device according to claim 4, wherein
the first insulating film further includes:
a fourth film portion between the third insulating film and the via electrode, and
a fifth film portion between the fourth insulating film and the via electrode,
the gate electrode is made of a first conductive material, and
the via electrode is made of the first conductive material and is electrically connected to the gate electrode.

6. The semiconductor device according to claim 1, further comprising:
a third insulating film provided on or above the first film portion of the first insulating film and made of a third insulating material that is different from the first insulating material, wherein
the oxide semiconductor penetrates and contacts the third insulating film.

7. The semiconductor device according to claim 6, wherein
oxygen permeability of the first insulating material is lower than oxygen permeability of the third insulating material.

8. The semiconductor device according to claim 1, further comprising:
a fourth insulating film provided on or below the second film portion of the first insulating film and made of a fourth insulating material that is different from the first insulating material, wherein
the oxide semiconductor penetrates and contacts the fourth insulating film.

9. The semiconductor device according to claim 8, wherein
oxygen permeability of the first insulating material is lower than oxygen permeability of the fourth insulating film.

10. The semiconductor device according to claim 1, wherein
the first electrode is made of a metal oxide.

11. A semiconductor device, comprising:
a substrate extending in a first direction;
a first oxide semiconductor extending in a second direction intersecting the first direction above the substrate;
a first interlayer insulating film that extends in a plane parallel to the substrate, wherein the first oxide semiconductor penetrates the first interlayer;
a first electrode electrically connected to one end of the first oxide semiconductor and including oxygen, indium, and tin;
a first film provided between the first oxide semiconductor and the first electrode, electrically connected to the first oxide semiconductor and the first electrode, and formed of a semiconductor or a conductor; and
a gate electrode that extends along the first direction and opposes the first oxide semiconductor across a gate insulating film, wherein
the first film contains atoms, binding energy of which with oxygen atoms is greater than binding energy between oxygen atoms and indium atoms in the first electrode.

12. The semiconductor device according to claim 11, wherein
the first film includes a potion that is between the first interlayer insulating film and the first electrode.

13. The semiconductor device according to claim 11, wherein
the gate insulating film surrounds the first oxide semiconductor,
the first interlayer insulating film surrounds a portion of the gate insulating film, and
the first film contacts the first interlayer insulating film, the gate insulating film, and the first oxide semiconductor.

14. The semiconductor device according to claim 11, further comprising:
a second interlayer insulating film, wherein
the first interlayer insulating film is between the gate electrode and the second interlayer insulating film,
the first film is surrounded by and exposed from the second interlayer insulating film, and
the first electrode is surrounded by the second interlayer insulating film, and is not exposed form the second interlayer insulating film.

15. The semiconductor device according to claim 11, wherein
the first film is a second oxide semiconductor that is different from the first oxide semiconductor.

16. The semiconductor device according to claim 15, wherein
each of the first oxide semiconductor and the second oxide semiconductor includes indium, gallium, zinc, and oxygen.

17. The semiconductor device according to claim 16, wherein
a composition ratio of indium, gallium, and zinc in the first oxide semiconductor is different from a composition ratio of indium, gallium, and zinc in the second oxide semiconductor.

18. The semiconductor device according to claim 11, wherein
the first film includes gallium.

19. The semiconductor device according to claim 11, wherein
the first film contacts the first electrode and the first oxide semiconductor, and
an area of contact between the first film and the first electrode is greater than an area of contact between the first film and the first oxide semiconductor.

20. A semiconductor memory device, comprising:
a substrate extending in a first direction;
a gate electrode extending along the first direction above the substrate;
an oxide semiconductor that extends in a second direction intersecting the first direction above the substrate and penetrates the gate electrode;
a first electrode electrically connected to one end of the oxide semiconductor;
a second electrode electrically connected to the other end of the oxide semiconductor;
a first insulating film made of a first insulating material and including:
a first film portion that covers an upper surface of the gate electrode,
a second film portion that covers a lower surface of the gate electrode, and
a third film portion that covers a first side surface of the gate electrode that extends along a side surface of the oxide semiconductor;
a first capacitor electrode connected to the first electrode;
a second capacitor electrode that opposes the first capacitor electrode; and
a dielectric film between the first capacitor electrode and the second capacitor electrode.
